(19) United States
(12) Patent Application Publication
(10) Pub. No.: US 2009/0269606 A1
(43) Pub. Date: Oct. 29, 2009

(54) METHOD FOR FORMING METAL FILM AND METHOD FOR FORMING METAL PATTERN

(75) Inventor: Kazuhiko Matsumoto, Minami-Ashigara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFLIM Corporation, Minato-ku, Tokyo (JP)

(21) Appl. No.: 12/093,117

(22) PCT Filed: Nov. 8, 2006
(86) PCT No.: PCT/JP2006/322238

§ 371 Date: May 8, 2008

(30) Foreign Application Priority Data
Nov. 8, 2005 (JP) 2005-323442

(51) Int. Cl. B32B 3/10; C25D 5/54; H05K 3/10; C25D 5/02

(52) U.S. Cl. 428/553; 205/50; 205/158; 205/126

(57) ABSTRACT

The present invention provides a method for forming a metal film including: (a1) a step of providing, on a substrate, a polymer layer that includes a polymer containing a functional group that interacts with a metal ion or a metal salt, the polymer directly chemically bonding to the substrate; (a2) a step of applying a metal ion or a metal salt to the polymer layer; (a3) a step of reducing the metal ion or the metal salt to form a conductive layer having a surface resistivity of from 10 to 100 kΩ/square; and (a4) a step of forming a conductive layer having a surface resistivity of 1×10⁻¹ Ω/square or less by electroplating.

### FIELD OF THE INVENTION

The present invention relates to a method for forming a metal film and a method for forming a metal pattern, and in particular to a method for forming a metal film and a method for forming a metal pattern applicable to metal wiring boards and printed wiring boards.

### BACKGROUND OF THE INVENTION

Metal films formed on a substrate are used in various electric appliances by etching into a pattern form. In a metal film (metal substrate) formed on a substrate, roughening treatment is carried out to the substrate surface so as to develop an anchoring effect in order to provide adhesiveness between the substrate and the metal layer. As a result, the substrate interface portion of the completed metal film is irregular, and so the high frequency characteristics thereof deteriorate when the metal film is used for electrical wiring lines. Furthermore, when forming such a metal substrate, a complicated process of treating the substrate with a strong acid, such as chromic acid, is required in order to carry out such roughening treatment of the substrate.

The main known conventional metal pattern forming methods are “subtractive processes”, “semi-additive processes”, and “fully-additive processes”.

A subtractive process is a method of: providing a photosensitive layer, which is photosensitive to irradiation with actinic radiation, on a metal layer formed on a substrate; carrying out image-wise light-exposure and developing to form a resist image; then etching the metal layer to form a metal pattern; and finally separating the resist therefrom.

In substrates used with this technique, in order to provide adhesiveness between the substrate and the metal layer, roughening treatment is carried out to the substrate interface, and adhesiveness is generated due to an anchoring effect. As a result, the substrate interface portion of the completed metal film is irregular, and so the high frequency characteristics thereof deteriorate when the metal film is used for electrical wiring lines. Furthermore, when forming such a metal substrate, a complicated process of treating the substrate with a strong acid, such as chromic acid, is required in order to carry out roughening treatment of the substrate.

In order to address these issues, a method is proposed for minimizing the irregularities (roughness) of the substrate and for simplifying the treatment process of the substrate. This method involves performing surface modification by grafting a radical polymerizable compound to the substrate surface (see, for example, Japanese Patent Application Laid-Open (JP-A) No. 58-196238, and Advanced Materials 2000, No. 20, pages 1481 to 1494). However, expensive equipment (such as a γ-ray generator or an electron beam generator) is required for this method. Moreover, since the substrate used by this method is not one to which polymerization initiation groups used as the starting point of graft polymerization are introduced, the graft polymer may not be generated at a sufficient level in practice. Furthermore, even if the metal substrate produced by this technique is patterned using a subtractive process, there are inherent problems with the subtractive process. Namely, in order to form a metal pattern with extremely thin line widths using a subtractive process, an over etching method is effective in which the line width after etching becomes narrower than the line width of the resist pattern itself. However, when attempting to form a fine metal pattern directly by such an over etching method, line smudging, thin spots/cracks, discontinuities and the like readily occur, therefore it is difficult to form metal patterns of 30 μm or less from the viewpoint of forming favorable fine metal patterns. Moreover, wasteful etching processes are required to remove metal thin film from areas other than the pattern portions, and environmental and cost issues arise, such as the expense incurred for treatment of the metal waste fluid produced by such etching processes.

In order to address the above issues, a metal pattern forming technique called a semi-additive process is proposed. With a semi-additive process, a base substrate layer of Cr or the like is thinly formed by metal plating or the like on a substrate, and a resist pattern is formed on the substrate metal layer. Then, after forming a metal layer of Cu or the like by metal plating on the base substrate metal layer in regions other than those of the resist pattern, a wiring pattern is formed by removing the resist pattern. Thereafter, the base substrate metal layer is etched using the wiring pattern as a mask, and a metal pattern is formed in regions other than those of the resist pattern. Since this is an etching-less technique, a fine wiring pattern of 30 μm or less is readily formed, and this technique is effective from the environmental and cost perspectives since metal is only deposited by metal plating in the required portions. However, in order to provide adhesiveness between the substrate and the metal pattern with this technique, roughening treatment of the substrate surface needs to be performed, and as a result the substrate interface portion of the completed metal pattern is irregular, and the high frequency characteristics deteriorate when applied to electrical wiring.

Moreover, a fully-additive process is proposed as a metal pattern forming technique. In a fully-additive process, a resist pattern is formed on a substrate, metal is deposited on regions other than those of the resist pattern by metal plating, and the resist pattern is then removed. Since this technique is also an etching-less technique, a fine wiring pattern of 30 μm or less is readily formed, but there are the same issues as with semi-additive processes. Accordingly, a new metal pattern forming technique is desired which is capable of forming a fine wiring pattern, has few irregularities of the substrate interface, and produces little etching waste liquid.

Such metal patterns have application in semiconductor devices as lines on a printed circuit board (conductive film). Recently, the requirements for carrying out high speed processing of mass data are increasing for electronic equipment. Moreover, internal clock frequencies and external clock frequencies and the number of contact pins are increasing every year in semiconductor devices used for image processing, communications control, and the like. For achieving high-speed conduction, it is important to suppress signal delay and attenuation. Making the dielectric constant low is effective for suppressing the propagation delay of a signal, and making the dielectric constant and the dielectric tangent low, respectively, is effective for suppressing dielectric loss. Since the dielectric constant is related to the dielectric loss by the square root of the dielectric constant, in reality the dielectric tangent has a larger impact. Accordingly, with respect to material characteristics, the use of an insulating material having low dielectric tangent characteristics is advantageous from the standpoint of speeding up.

Moreover, increasing the smoothness of an electric conductor surface contributes greatly to increasing density. Surface roughening is performed in conventional build-up printed circuit boards, in order to secure peel strength, but the reality is that such irregularities, of the order of several microns, have become a hindrance to further micronization of wiring lines. In particular, there is a problem of impairing suitability for high frequency transmission in semiconductor devices, with a wiring board using a substrate to which surface roughening has been carried out. Therefore, a method is desired for forming a fine and dense metal pattern with high adhesiveness on a smooth insulating substrate, for the formation of printed wiring boards applicable to semiconductor devices.

### DISCLOSURE OF THE INVENTION

### Subjects to be Addressed by the Invention

The present invention has been made in consideration of the above conventional technical problems, and an object thereof is to provide a simple metal film forming method which is capable of forming a metal film with excellent adhesiveness to a substrate, sufficient conductivity, and with low irregularities at the substrate interface thereof.

Another object of the present invention is to provide a simple metal pattern forming method capable, without performing etching, of forming a fine metal pattern with excellent adhesiveness to a substrate, sufficient conductivity, and with low irregularities at the substrate interface thereof.

### Means for Solving the Problem

The above-described problems may be solved by the following metal film forming method and metal pattern forming method.

A first aspect of the method for forming a metal film of the present invention is a method of forming a metal film including the steps of:

(a1) providing, on a substrate, a polymer layer that includes a polymer containing a functional group that interacts with a metal ion or a metal salt, the polymer directly chemically bonding to the substrate;

(a2) applying a metal ion or a metal salt to the polymer layer;

(a3) reducing the metal ion or the metal salt to form a conductive layer having a surface resistivity of from 10 to 100 kΩ/square; and

(a4) forming a conductive layer having a surface resistivity of 1×10⁻¹ Ω/square or less by electroplating.

In the following explanation, the method for forming a metal film of this aspect may sometimes be referred to as “metal film forming method (1)”.

A second aspect of the method for forming a metal film of the present invention is a method for forming a metal film including the steps of:

(b1) providing, on a substrate, a polymer layer that includes a polymer containing a functional group that interacts with a metal colloid, the polymer directly chemically bonding to the substrate;

(b2) applying a metal colloid to the polymer layer to form a conductive layer having a surface resistivity of from 10 to 100 kΩ/square; and

(b3) forming a conductive layer having a surface resistivity of 1×10⁻¹ Ω/square or less by electroplating.

In the following explanation, the method for forming a metal film of this aspect may sometimes be referred to as “metal film forming method (2)”.

A first aspect of the method for forming a metal pattern of the present invention is a method for forming a metal pattern including:

(c1) providing, on a substrate, a polymer layer that includes a polymer containing a functional group that interacts with a metal ion or a metal salt, the polymer directly chemically bonding to the substrate;

(c2) applying a metal ion or a metal salt to the polymer layer;

(c3) reducing the metal ion or the metal salt to form a conductive layer having a surface resistivity of from 10 to 100 kΩ/square;

(c4) forming a pattern-shaped resist layer on the conductive layer having a surface resistivity of from 10 to 100 kΩ/square;

(c5) forming, in a region where the resist layer is not formed, a pattern-shaped conductive layer having 1×10⁻¹ Ω/square or less by electroplating;

(c6) separating the resist layer; and

(c7) removing the conductive layer formed in the step (c3) from the region that has been protected by the resist layer.

In the following explanation, the method for forming a metal pattern of this aspect may sometimes be referred to as “metal pattern forming method (1)”.

A second aspect of the method for forming a metal pattern of the present invention is a method for forming a metal pattern including the steps of:

(d1) providing, on a substrate, a polymer layer that includes a polymer containing a functional group that interacts with a metal colloid, the polymer directly chemically bonding to the substrate;

(d2) applying a metal colloid to the polymer layer to form a conductive layer having a surface resistivity of from 10 to 100 kΩ/square;

(d3) forming a pattern-shaped resist layer on the conductive layer having a surface resistivity of from 10 to 100 kΩ/square;

(d4) forming, in a region where the resist layer is not formed, a pattern-shaped conductive layer having a surface resistivity of 1×10⁻¹ Ω/square or less by electroplating;

(d5) separating the resist layer; and

(d6) removing the conductive layer formed in step (d2) from the region that has been protected by the resist layer.

In the following explanation, the method for forming a metal pattern of this aspect may sometimes be referred to as “metal pattern forming method (2)”.

A third aspect of the method for forming a metal pattern of the present invention is a method for forming a metal pattern including the steps of:

(e1) providing, on a substrate, a pattern-shaped polymer layer that includes a polymer containing a functional group that interacts with a metal ion or a metal salt, the polymer directly chemically bonding to the substrate;

(e2) applying a metal ion or a metal salt to the polymer layer;

(e3) reducing the metal ion or the metal salt to form a conductive layer having a surface resistivity of from 10 to 100 kΩ/square; and

(e4) forming a conductive layer having a surface resistivity of 1×10⁻¹ Ω/square or less by electroplating.

In the following explanation, the method for forming a metal pattern of this aspect may sometimes be referred to as “metal pattern forming method (3)”.

A fourth aspect of the method for forming a metal pattern of the present invention is a method for forming a metal pattern including the steps of:

(f1) providing, on a substrate, a pattern-shaped polymer layer that includes a polymer containing a functional group that interacts with a metal colloid, the polymer directly chemically bonding to the substrate;

(f2) applying a metal colloid to the polymer layer to form a conductive layer having a surface resistivity of from 10 to 100 kΩ/square; and

(f3) forming a pattern-shaped conductive layer having a surface resistivity of 1×10⁻¹ Ω/square or less by electroplating.

In the following explanation, the method for forming a metal pattern of this aspect may sometimes be referred to as “metal pattern forming method (4)”.

The metal ion or the metal salt used in the present invention is preferably a metal ion or salt of a metal chosen from the group consisting of copper, silver, gold, nickel, and chromium.

An additive is preferably included in the electroplating bath used for the present invention. The electroplating of the present invention is preferably carried out at a current density of from 0.1 to 3 mA/cm² until consumption of electricity reaches from 1/10 to ¼ of the total consumption of the electricity from the commencement of electric current flow to the termination of electric current flow.

A “substrate” in the present invention refers to something with a surface to which a polymer is able to directly chemically bond. For example, when chemically bonding a polymer directly to a resin film, the term “substrate” refers to the resin film itself, and when an intermediate layer, such as a polymerization initiation layer, is provided on a surface of a base material such as a resin film, and a polymer is chemically bonded directly to this surface, then the term “substrate” refers to the film base material and the polymerization initiation layer provided therewith.

In the following, a functional group that interacts with a metal ion, a metal salt, or a metal colloid may be referred to as an “interactive group”, for convenience.

The metal film obtained with the metal film forming method of the present invention, or the metal pattern obtained with the metal pattern forming method of the present invention, is preferably a metal film or a metal pattern that is provided on a substrate having surface irregularities of no more than 500 nm, and the adhesiveness of such a metal film or metal pattern to such a substrate is preferably 0.2 kN/m or more.

By using a substrate with surface irregularities no more than 500 nm, the surface irregularities of a polymer layer formed thereon also becomes no more than 500 nm. By performing electroplating after applying a metal ion or a metal salt to such a polymer layer and reducing it, or after applying a metal colloid thereto, a state is achieved where the metal used in the metal plating penetrates into the polymer layer (a composite state), and further the metal plating film is formed on the polymer layer. Consequently, the roughness of the interface of the thus formed metal film (or metal pattern) and the substrate (the interface of the metal with the polymer layer (organic component)) becomes slightly rougher due to the plating metal penetrated into the polymer pattern, in comparison to the roughness of the surface of the polymer pattern. However, since this increase in roughness is only by a minor amount, the irregularities at the interface of the metal plating layer (inorganic component) with the polymer layer (organic component) of a metal film (or a metal pattern) may be suppressed to the extent that the high frequency characteristics of the metal film (or the metal pattern) do not deteriorate. Therefore, when using such a metal pattern for electrical wiring, superior high frequency characteristics may be obtained. High frequency characteristics are characteristics of reduction in transmission loss during high frequency power transmission, and in particular, characteristics of reduction in conductor loss.

After detailed investigations into the polymer layer (organic component) which is present between such a metal film (or a metal pattern) and a substrate, the polymer layer which is present between the metal film and the substrate is found to have a portion, containing particles of a metal which has been deposited by electroplating at 25% by volume or more thereof, to a thickness of 0.05 μm or more in a direction from the interface of the substrate and the metal film, and it is thought that the presence of these particles of metal or the like provides a composite state that is beneficial to the adhesiveness of the metal film.

Here, by reducing the irregularities of the substrate surface, the roughness of the substrate interface portion with the metal film (or a metal pattern) may be further suppressed, and the high frequency characteristics of the obtained metal film (or a metal pattern) may be improved. In view of this, a substrate with surface irregularities of no more than 100 nm is preferably used.

Moreover, it is thought that the high adhesiveness of the formed metal film to the substrate is achieved due to the minimized surface irregularity of the substrate that has been surface-modified by surface grafting, and the metal portion at the substrate interface being in a hybrid state with the graft polymer bonded directly to the substrate.

In the present invention, Rz according to JIS B0601 is used as the standard for surface roughness, namely “the difference between the average of the Z data from the maximum peak to the fifth highest peak, and the average of the Z data from the minimum valley to the fifth lowest valley”.

When the metal pattern obtained with the application of the present invention is used as a conductive material, such as in a wiring board, the less the irregularities at the interface of the formed metal film (metal pattern), i.e., the interface of wiring metal portions with the organic material are, the less the power loss during high frequency power transmission (transmission loss) becomes.

Therefore, in a printed wiring board using a metal pattern obtained according to the present invention as a conductive layer (wiring), fine wiring lines with excellent smoothness and adhesiveness to the substrate may be formed, while achieving excellent high frequency characteristics.

### EFFECT OF THE INVENTION

According to the present invention, a simple metal film forming method can be provided which is capable of forming a metal film with excellent adhesiveness to a substrate, sufficient conductivity, and with low irregularities at the interface with the substrate.

Moreover, according to the present invention, a simple metal pattern forming method is provided which is capable of forming a fine metal pattern without performing etching, with excellent adhesiveness to a substrate, sufficient conductivity, and with low irregularities at the interface with the substrate.

### BEST MODE OF CARRYING OUT THE INVENTION

The present invention will now be explained in detail. The metal film forming method of the present invention will first be explained.

Metal Film Forming Method (1)

The first aspect of the metal film forming method of the present invention includes the steps of:

(a1) providing, on a substrate, a polymer layer that includes a polymer containing a functional group that interacts with a metal ion or a metal salt, the polymer directly chemically bonding to the substrate;

(a2) applying a metal ion or a metal salt to the polymer layer;

(a3) reducing the metal ion or the metal salt to form a conductive layer having a surface resistivity of from 10 to 100 kΩ/square; and

(a4) forming a conductive layer having a surface resistivity of 1×10⁻¹ Ω/square or less by electroplating.

Step (a1)

In step (a1), a polymer layer is provided on a substrate, the polymer layer including a polymer containing a functional group (an interactive group) that interacts with a metal ion or a metal salt, and directly chemically bonding to the substrate.

The step (a1) preferably includes: a step (a1-1) of preparing a substrate having a polymerization initiation layer containing a polymerization initiator formed on a base material; and a step (a1-2) of providing, on the polymerization initiation layer that has been formed on the substrate, a polymer layer including a polymer containing an interactive group, and is directly chemically bonding to the base material.

In step (a1-2), it is preferable that the polymer is directly chemically bonded to the entire surface of the substrate by contacting a polymer containing a polymerizable group and an interactive group with the polymerization initiation layer formed on the substrate, and then applying energy thereto.

Surface Graft

Formation of the polymer layer on the substrate is performed by a general technique called surface graft polymerization. The graft polymerization method includes applying an active species to a polymer compound chain, and further polymerizing another monomer thereto that initiates polymerization with the active species, thereby synthesizing a graft polymer. Specifically, this polymerization is called surface graft polymerization, when the polymer compound to which the active species is applied forms a surface of a solid body.

Any known methods described in publications can be applied as the surface graft polymerization method of the present invention. For example, a photo-graft polymerization method and a plasma irradiation graft polymerization method are described as surface graft polymerization methods at page 135 of Shin Kobunshi Jikken-gaku (New Polymer Experimentology) 10, edited by the Society of Polymer Science, Japan, published in 1994 by Kyoritsu Shuppan Co., Ltd. There are also radiation irradiation graft polymerization methods, such as using γ-rays or an electron beam, described at pages 203 and 695 of Kyuchaku Gijutsu Binran (Handbook of Adsorption Technology), under the editorial supervision of Takeuchi, published by NTS, Inc., February 1999.

Specific methods of photo-graft polymerization which may be used include the methods described in JP-A No. 63-92658, JP-A No. 10-296895, and JP-A No. 11-119413.

As techniques for producing a polymer layer directly chemically bonding at the terminals of the polymer compound chains, in addition to the above methods, a method can also be applied in which reactive functional groups, such as a trialkoxysilyl group, an isocyanate group, an amino group, a hydroxyl group, or a carboxyl group, are provided to a terminal end of a polymer compound chain, and a coupling reaction of these groups and functional groups present on the substrate surface to form a polymer layer.

A photo-graft polymerization method is preferable from the standpoint of generating more surface graft polymers.

Substrate

The substrate of the present invention has a surface having a functionality such that a terminal end of a polymer compound containing an interactive group is able to directly, or via a trunk polymer compound, chemically bond thereto. A base material itself may have such a surface property, or a separate intermediate layer may be provided on such a base material, or the intermediate layer may have such characteristics.

Moreover, as a technique for producing a surface to which the terminal end of a chain of a polymer compound containing an interactive group is chemically bonded via a trunk polymer compound, there is a method including synthesizing a polymer compound containing an interactive group and a functional group capable of carrying out a coupling reaction with a functional group at the substrate surface, and forming the surface by the coupling reaction of this polymer compound and the functional group at the substrate surface. There is another method including, when the substrate surface has a property of generating a radical species, synthesizing a polymer compound containing a polymerizable group and an interactive group, applying this polymer compound onto the substrate interface, generating the radical species, and causing a polymerization reaction of the substrate surface with the polymer compound to form the surface.

In the present invention, an active species is applied to a substrate surface as described above, and a graft polymer is generated starting from the active species. When generating the graft polymer, it is preferable to form a polymerization initiation layer containing a polymerization initiator on the substrate (step (a-1)), from a standpoint of efficiently generating active sites to generate more surface graft polymers.

The polymerization initiation layer is preferably formed as a layer containing a polymerizable compound and a polymerization initiator.

The polymerization initiation layer of the present invention may be formed by dissolving the essential components in a solvent in which they are soluble, disposing the solution on a substrate surface by a method such as coating, and curing the film by heating or light-irradiation thereon.

(a) Polymerizable Compound

There are no particular limitations to the polymerizable compound used for the polymerization initiation layer, as long as it has good adhesiveness to a base material, and as long as a surface graft polymer is generated by the application of energy thereto, such as by actinic radiation irradiation. Polyfunctional monomers and the like may be used, but a particularly preferable embodiment is one using a hydrophobic polymer containing a polymerizable group within its molecule.

Specific examples of such a hydrophobic polymer include: diene-containing homopolymers, such as polybutadiene, polyisoprene, and polypentadiene, and allyl group-containing homopolymers, such as allyl(meth)acrylate, and 2-allyloxyethyl methacrylate; binary or multicomponent copolymers which include as a structural unit a diene-containing monomer, such as butadiene, isoprene, pentadiene, and the like, or an allyl group-containing monomer, such as styrene, (meth)acrylate, and (meth)acrylonitrile; and linear or three-dimensional copolymers that have a carbon-carbon double bond within their molecules, such as an unsaturated polyester, an unsaturated polyepoxide, an unsaturated polyamide, an unsaturated polyacrylate, a high density polyethylene, and the like.

It should be noted that in this specification when referring to “acrylic and/or methacrylic”, this is sometimes written as “(meth)acrylic”.

The amount contained of the polymerizable compound in the polymerization initiation layer is preferably in the range of from 0 mass % to 100 mass % in terms of solid content, and the range from 10 mass % to 80 mass % is particularly preferable.

(b) Polymerization Initiator

A polymerization initiator for exhibiting a polymerization initiation ability with energy application is included in the polymerization initiation layer. Such a polymerization initiator may be suitably selected according to the application from known thermal polymerization initiators, photo polymerization initiators and the like which exhibit a polymerization initiation ability with application of certain energy thereto, for example, irradiation of actinic radiation, heating, irradiation of an electron beam, and the like. A photopolymerization initiator is preferably employed, from among these, since photopolymerization is preferable from the standpoint of manufacturability.

There are no particular limitations to the photopolymerization initiator, as long as it is active in the irradiated actinic radiation and is capable of surface graft polymerization, and, for example, a radical polymerization initiator, an anionic polymerization initiator, a cationic polymerization initiator, and the like, may be used. Among these, a radical polymerization initiator is preferable from the standpoint of reactivity.

Specific examples of such a photopolymerization initiator include, for example: acetophenones such as p-tert-butyltrichloroacetophenone, 2,2′-diethoxyacetophenone, and 2-hydroxy-2-methyl-1-phenyl propan-1-one; ketones such as benzophenone (4,4′-bisdimethylaminobenzophenone), 2-chlorothioxantone, 2-methylthioxantone, 2-ethylthioxantone, and 2-isopropylthioxantone; benzoin ethers, such as benzoin, benzoin methyl ether, benzoin isopropyl ether, and benzoin isobutyl ether; benzyl ketals such as benzyl dimethyl ketal, and hydroxycyclohexyl phenyl ketone; and the like.

The amount contained of the polymerization initiator in the polymerization initiation layer is preferably in the range of from 0.1 mass % to 70 mass % in terms of solid content, and the range from 1 mass % to 40 mass % is particularly preferable.

There are no particular limitations to the solvent used for coating a polymerizable compound and a polymerization initiator, as long as it dissolves these components therein. A solvent whose boiling point is not too high is preferable from the standpoints of ease of drying and workability, and specifically a solvent with a boiling point of from about 40° C. to about 150° C. may be selected.

Specific examples of the solvent include acetone, methyl ethyl ketone, cyclohexane, ethyl acetate, tetrahydro furan, toluene, ethylene glycol monomethyl ether, ethylene glycol monoethyl ether, ethylene glycol dimethyl ether, propylene glycol monomethyl ether, propylene glycol monoethyl ether, acetylacetone, cyclohexanone, methanol, ethanol, 1-methoxy-2-propanol, 3-methoxypropanol, diethylene glycol monomethyl ether, diethylene glycol monoethyl ether, diethylene glycol dimethyl ether, diethylene glycol diethylether, propylene glycol monomethyl ether acetate, propylene glycol monoethyl ether acetate, 3-methoxypropyl acetate, and the like.

These solvents may be used singly or as mixtures thereof. A solid concentration of from 2 to 50 mass % is suitable for the coating liquid.

The coating amount when forming a polymerization initiation layer on a substrate is preferably from 0.1 g/m² to 20 g/m² dry weight, and more preferably from 1 g/m² to 15 g/m², from the standpoints of exhibiting sufficient polymerization initiation ability, maintaining a film property and preventing the film from peeling.

When forming a polymerization initiation layer in the present invention, as described above, the composition for the above polymerization initiation layer formation is disposed by coating or the like on the surface of a base material, and then the solvent is removed to form a film. When this is carried out, it is preferable to cure the film by performing heating and/or light-irradiation. It is particularly preferable to carry out a certain amount of curing of the polymerizable compound in advance, by pre-curing by light-irradiation after drying with heat, since the occurrences of the whole polymerization initiation layer falling off after grafting may be effectively suppressed thereby. The rational for using light-irradiation for pre-curing is similar to that described for the aforementioned photo-polymerization initiator.

Conditions of heating temperature and time may be selected so that there is sufficient drying of the coating liquid, however, a temperature of 100° C. or less for a time period of 30 minutes or less is preferable from the standpoint of applicability to production, with drying conditions of a drying temperature in the range of 40° C. to 80° C. and a drying time of 10 minute or less being more preferable.

After heating and drying, a light source used for the later described grafting reaction may be used for light-irradiation that is optionally performed. Preferably, the light-irradiation is performed to the extent that complete radical polymerization is not carried out, while the polymerizable compound present in the polymerization initiation layer is partially radical-polymerized, from the standpoint of not impeding formation of a bond between the active sites of the polymerization initiation layer and the graft chain that is carried out by applying energy during the subsequent grafting reaction. The light-irradiation duration depends on the strength of the light source, but it is generally preferably 30 minutes or less. As a rough guide to such pre-curing, the amount may be such that the residual film proportion after washing out the solvent is 10% or less, and the proportion of the initiator remaining after pre-curing is 1% or greater.

Base Material

The base material used for the present invention is preferably a dimensionally stable plate-shaped member, and examples include, for example: paper, plastic (for example, polyethylene, polypropylene, polystyrene and the like) laminated paper, a metal plate (for example, aluminum, zinc, copper and the like), plastic films (for example, cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinyl acetal, polyimide, epoxy and the like), paper, plastic films, and the like with a metal laminated, or vapor-deposited, thereon. A polyester film or a polyimide film is preferable as the base material used for the present invention.

Moreover, the metal film obtained according to the present invention is applicable to semiconductor packages, various electric wiring boards, and the like by patterning the metal film by etching. When used in such applications, an insulating resin, shown below, is preferably used as the substrate.

Examples of such an insulating resin include resins such as polyphenylene ethers or modified polyphenylene ethers, cyanate ester compounds, and epoxy compounds. A substrate formed with a thermosetting resin composition containing one or more sorts of such resins is preferably used. When using such resins in combinations of two or more as a resin composition, preferable combinations include: polyphenylene ether or modified polyphenylene ether with a cyanate ester compound; polyphenylene ether or modified polyphenylene ether with an epoxy compound; and polyphenylene ether or modified polyphenylene ether with a cyanate ester compound and an epoxy compound.

When forming a substrate with such a thermosetting resin composition, inorganic fillers chosen from the group which includes silica, talc, aluminum hydroxide, and magnesium hydroxide are preferably not included therein, and a thermosetting resin composition which includes a bromine compound or a phosphorus compound is preferable.

Moreover, other insulating resins include 1,2-bis(vinylphenylene)ethane resin, or a modified resin of 1,2-bis(vinylphenylene)ethane resin with a polyphenylene ether resin. Such resins are described in detail, for example, in pages 1252 to 1258 of the 92nd volume of “Journal of Applied Polymer Science” (2004), by Satoru AMOU.

Furthermore, preferable examples include: commercially available liquid crystal polymers, with a representative example thereof being “VECSTAR” (trade name, made by Kuraray Co., Ltd.), and fluororesins and the like, with a representative example thereof being polytetrafluoroethylene (PTFE).

Among such resins, fluororesins (PTFE) have the most excellent high frequency characteristics of polymer materials. However, since they are thermoplastic resins with a low Tg, they have poor dimensional stability to heat, and the mechanical strength and the like thereof is inferior to those of thermosetting resin materials. Further, they also have inferior molding and processing characteristics. Moreover, thermoplastic resins, such as polyphenylene ether (PPE), may also be used after alloying with a thermosetting resin and the like. Examples that may be used include an alloyed resin of PPE with an epoxy resin or triarylisocyanate, or an alloyed resin of a PPE resin, into which a polymerizable functional group has been introduced, with another thermosetting resin.

Although dielectric characteristics of an epoxy resin are insufficient as they are, improvements have been achieved by introducing a bulky skeleton or the like. In this way, a resin is preferably used which takes advantage of the different characteristics from other resins to compensate for any deficiencies thereof, by introducing such a structure or by carrying out modification or the like.

For example, although a cyanate ester is a thermosetting resin which has the most excellent dielectric characteristics among the thermosetting resins, it is rarely used on its own, and is more normally used as a modified resin, such as with an epoxy resin, a maleimide resin, or a thermoplastic resin. Details relating to such matters are described at page 35 of “Denshi Gijutsu” (Electronic Technology), No. 9, 2002, and one of these resins, or a similar insulating resin, may be chosen with reference thereto.

When applying the metal film obtained by the present invention to a semiconductor package, or to various electrical wiring applications and the like, it is effective to provide a low dielectric constant and a low dielectric tangent to the substrate, from the standpoint of carrying out mass data processing at high speed, and in order to suppress delay and attenuation of signals. Details regarding the materials having a low dielectric tangent are described at page 397 of “Electronics Jissou Gakkaishi” (Electronics Packaging Institution Journal), volume 7, No. 5, (2004). It is particularly preferable to adopt an insulating material having low dielectric tangent characteristics from a standpoint of improvements in speed.

Specifically, a substrate which includes an insulating resin whose dielectric constant (relative dielectric constant) at 1 GHz is 3.5 or less, or a substrate having a layer containing an insulating resin on a base material, is preferably used as the substrate for such applications. Moreover, it is preferable that the substrate is one formed from an insulating resin whose dielectric tangent at 1 GHz is 0.01 or less, or is a substrate which has a layer containing such an insulating resin on a base material.

The dielectric constant and the dielectric tangent of such insulating resins can be measured using a conventional method. For example, these characteristics can be measured according to the methods described at page 189 of “Collection of Extracts of the 18th Institute of Electronics Packaging Institution Convention”, 2004, using a cavity resonator perturbation method (for example, an instrument for measuring ∈r and tan δ of a ultra-thin sheet, made by KEYCOM Corp.).

Thus, an insulating resin material may also be suitably selected for the present invention from standpoints of dielectric constant and dielectric tangent. Examples of insulating resins with a dielectric constant of 3.5 or less and a dielectric tangent of 0.01 or less include a liquid crystal polymer, a polyimide resin, a fluororesin, a polyphenylene ether resin, a cyanate ester resin, a bis(bisphenylene)ethane resin, modified resins thereof, and the like.

The irregularities on the surface of the base material applied to the metal film forming method of the present invention are preferably 500 nm or less, more preferably 200 nm or less, still more preferably 50 nm or less, and most preferably 20 nm or less.

Furthermore, the Rz (ten-point average roughness) of the surface of the base material is preferably 500 nm or less, more preferably 100 nm or less, still more preferably 50 nm or less, and most preferably 20 nm or less. It should be noted that the measuring method of Rz is the measurement undertaken according to JIS B0601 of “the difference between the average of the Z data from the maximum peak to the fifth highest peak, and the average of the Z data from the minimum valley to the fifth lowest valley”.

Graft Polymer Generation

As generation modes of the graft polymer in the step (a1), as described above, a method of using a coupling reaction between a functional group present on the substrate surface and a reactive functional group at a terminal end or side chain of a polymer compound, and a method of carrying out direct photo-graft polymerization of the substrate may be used.

In the present invention, preferred is a mode (step (a1-2)) including introducing a polymer containing a functional group (an interactive group) which interacts with an electroless plating catalyst or a precursor thereof and that directly chemically bonds to the base material, onto the substrate on which the polymerization initiation layer has been formed. Further preferred is a mode in which, after contacting the polymer containing a polymerizable group and an interactive group with the base material on which the polymerization initiation layer has been formed, the polymer is directly chemically bonded to the entire substrate of the base material by applying energy thereto. That is to say, a composition containing the compound containing a polymerizable group and an interactive group is contacted with the polymerization initiation layer formed on the base material surface, and directly bonded to the base material surface by the active species generated on the base material surface.

The above contact may be performed by immersing a base material in a liquid-state composition including the compound containing a polymerizable group and an interactive group.

However, as described later, a layer, containing a composition including a compound polymerizable group and an interactive group as a main component, may be formed on a substrate surface by an application method, from standpoints of handling and manufacturing efficiency.

<Method Using the Coupling Reaction Between a Functional Group Present on a Substrate Surface and a Reactive Functional Group at a Terminal End or Side Chain of a Polymer Compound>

In the present invention, any reactions may be applied as coupling reactions for generation of a graft polymer. Specific combinations of a functional groups on the substrate surface and a reactive functional group at a terminal end or side chain of the polymer compound include combinations of (—COOH, amine), (—COOH, aziridine) (—COOH, isocyanate), (—COOH, epoxy), (—NH₂, isocyanate), (—NH₂, aldehydes), (—OH, alcohol), (—OH, halogenated compound), (—OH, amine), and (—OH, acid anhydride). The combinations (—OH, polyvalent isocyanate) and (—OH, epoxy) are particularly preferable from a standpoint of high reactivity.

<Method of Direct Photo-Graft Polymerization to the Substrate>

(Monomers Having an Interactive Group and Capability of Photo-Graft Polymerization)

In the method of carrying out direct photo-graft polymerization to the substrate according to the present invention, the following monomers may be used as a compound having an interactive group and capability of directly chemically bonding to the substrate, when generating the graft polymer. Examples thereof include monomers which have functional groups such as a carboxyl group, a sulfonic group, a phosphoric group, an amino group or salts thereof, a hydroxyl group, an amide group, a phosphine group, an imidazole group, a pyridine group or salts thereof, or an ether group: for example, (meth)acrylic acid or an alkali metal salt or amine salt thereof, itaconic acid or an alkali metal salt or amine salt thereof, 2-hydroxyethyl(meth)acrylate, (meth)acrylamide, N-monomethylol(meth)acrylamide, N-dimethylol(meth)acrylamide, allylamine or a hydrohalic acid salt thereof, 3-vinylpropionic acid or an alkali metal salt or an amine salt thereof, vinylsulfonic acid or an alkali metal salt or an amine salt thereof, 2-sulfoethyl(meth)acrylate, polyoxyethyleneglycol mono(meth)acrylate, 2-acrylamide-2-methylpropanesulfonic acid, acid phosphooxy polyoxyethyleneglycol mono(metha)acrylate, and N-vinyl pyrrolidone (structure as shown below). These monomers may be used singly on their own, or in combinations of two or more thereof.

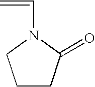

(Polymers which have an Interactive Group and which Directly Chemically Bond to a Substrate)

Examples of a polymer that contains an interactive group and that directly chemically bonds to the substrate include polymers generated from a monomer containing an interactive group. Moreover, a preferably used polymer is a polymer containing a polymerizable group and an interactive group, i.e., a homopolymer or copolymer obtained using at least one monomer with an interactive group, into which an ethylene addition polymerizable unsaturated group (polymerizable group) such as a vinyl group, an allyl group, and a (meth) acrylic group is introduced as the polymerizable group. Such a polymer containing a polymerizable group and an interactive group has a polymerizable group at least at a terminal end or side chain thereof, wherein the polymerizable group is preferably present at a terminal end, and is more preferably present at both of a terminal end and at a side chain.

In the present invention, the reason that a polymer containing a polymerizable group and an interactive group is preferably used is as follows. Namely, performing graft polymerization with a monomer using a method of immersing in a monomer solution is difficult to be used for mass production, considering manufacturability. Moreover, in a method of coating a monomer solution, it is especially difficult to maintain uniformity of the monomer solution on a base material up till light-irradiation. Furthermore, although a method is known of, after coating a monomer solution, covering with a film or the like, it is difficult to carry out such covering uniformly, and the covering operation itself becomes necessary, leading to a complicated operation. However, in contrast, if a polymer is used, it becomes solid after being applied, and therefore a uniform film can be formed and mass production is facilitated.

The following monomers may be used as a monomer containing an interactive group for synthesizing the above polymer. Examples thereof include monomers which have functional groups such as a carboxyl group, a sulfonic group, a phosphoric group, an amino group or salts thereof, a hydroxyl group, an amide group, a phosphine group, an imidazole group, a pyridine group or salts thereof, or an ether group: for example, (meth)acrylic acid or an alkali metal salt or amine salt thereof, itaconic acid or an alkali metal salt or amine salt thereof, 2-hydroxyethyl(meth)acrylate, (meth)acrylamide, N-monomethylol(meth)acrylamide, N-dimethylol(meth)acrylamide, allylamine or a hydrohalic acid salt thereof, 3-vinylpropionic acid or an alkali metal salt or an amine salt thereof, vinylsulfonic acid or an alkali metal salt or an amine salt thereof, 2-sulfoethyl(meth)acrylate, polyoxyethyleneglycol mono(meth)acrylate, 2-acrylamide-2-methylpropanesulfonic acid, acid phosphooxy polyoxyethyleneglycol mono(metha)acrylate, and N-vinylpyrrolidone (structure as shown below). These monomers may be used singly on their own, or in combinations of two or more thereof.

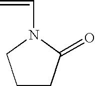

The polymer containing a polymerizable group and an interactive group may be synthesized as follows.

Examples of synthesis methods include:

i) a method of copolymerizing a monomer containing an interactive group with a monomer containing a polymerizable group;

ii) a method of copolymerizing a monomer containing an interactive group with a monomer containing a double bond precursor, and then introducing a double bond thereinto by treatment with a base or the like; and

iii) a method of reacting a monomer containing an interactive group with a monomer containing a polymerizable group, and then introducing a double bond (introducing a polymerizable group) thereinto.

From the standpoint of polymerizability, preferred are the methods of ii) copolymerizing a monomer containing an interactive group with a monomer containing a double bond precursor, and then introducing a double bond thereinto by treatment with a base or the like; and iii) reacting a monomer containing an interactive group with a monomer containing a polymerizable group, and then introducing a polymerizable group thereinto.

As the monomer containing an interactive group used for synthesizing the polymer containing a polymerizable group and an interactive group, the aforementioned monomer containing an interactive group may be used as a monomer containing an interactive group. Monomers may be used singly on their own, or in combinations of two or more thereof.

As the monomer containing a polymerizable group to be copolymerized with a monomer containing an interactive group, allyl(meth)acrylate, 2-allyloxyethyl methacrylate, and the like can be mentioned.

As the monomer containing a double bond precursor, 2-(3-chloro-1-oxopropoxy)ethyl methacrylate, 2-(3-bromo-1-oxopropoxy)ethyl methacrylate, and the like can be mentioned.

As the monomer containing a polymerizable group to be used for introducing an unsaturated group by reaction with a functional group in a polymer having an interactive group, such as a carboxyl group, an amino group or a salt thereof, a hydroxyl group or an epoxy group, (meth)acrylate, glycidyl (meth)acrylate, allyl glycidyl ether, 2-isocyanatoethyl (meth)acrylate, and the like can be mentioned.

Moreover, a macro-monomer may also be used in the present invention. Various manufacturing methods are proposed for the manufacturing method of a macro-monomer applicable to the present invention, such as, for example, those described in the Chapter 2 of “Macro-monomer Synthesis” in “Chemistry and Industry of Macro-monomer” (edited by Yuya YAMASHITA, published by IPC, Sep. 20, 1989).

Particularly applicable as the macro-monomer used in the present invention are: macro-monomers derived from a monomer containing a carboxyl group, such as acrylic acid or methacrylic acid and the like; sulfonic macro-monomers derived from a monomer such as 2-acrylamide-2-methylpropanesulfonic acid, vinyl styrene sulfonic acid or salts thereof; amide macro-monomers derived from a monomer such as (meth)acrylamide, N-vinylacetamide, N-vinylformamide, N-vinyl carboxylic acid; macro-monomers derived from a monomer containing a hydroxyl group, such as hydroxyethyl methacrylate, hydroxyethyl acrylate, glycerol monomethacrylate and the like; and macro-monomers derived from a monomer containing an alkoxy group or an ethylene oxide group, such as methoxyethyl acrylate, methoxy polyethylene glycol acrylate, and polyethylene glycol acrylate. Moreover, monomers which have a polyethylene glycol chain or a polypropylene glycol chain may also be applied as the macro-monomer used in the present invention.

The range of useful molecular weights of these macro-monomers is from 250 to 100,000, and a particularly preferable range is from 400 to 30,000.

There are no particular limitations to the solvent used for the composition containing the monomer containing an interactive group or the polymer containing a polymerizable group and an interactive group, as long as the monomer containing an interactive group, the polymerizable group, and the interactive group, which are the principal components of the composition, are soluble therein. A surfactant may also be added to the solvent.

Examples of solvents which can be used include, for example: alcohol solvents such as methanol, ethanol, propanol, ethylene glycol, glycerol, and propylene glycol monomethyl ether; acids like acetic acid; ketone solvents such as acetone, and cyclohexanone; and amide solvents such as formamide and dimethylacetamide.

Surfactants which may be added to the solvent as required may be any surfactant that dissolves in the solvent, and such surfactants include, for example: anionic surfactants, such as n-sodium dodecylbenzenesulfonate; cationic surfactants such as n-dodecyl trimethylammonium chloride; and nonionic surfactants such as polyoxyethylene nonylphenol ether (commercially available as, for example, EMULGEN 910, made by Kao Corporation, and the like), polyoxyethylene sorbitan monolaurate (commercially available as, for example, trade name “TWEEN 20” and the like), and polyoxyethylene lauryl ether.

When the composition is contacted in a liquid state, this may be carried out as desired, however, the coating amount for a coating layer of a composition containing an interactive group is preferably from 0.1 to 10 g/m² solids equivalent, and is particularly preferably from 0.5 to 5 g/m², from the standpoints of ensuring sufficient interaction with metal ions and the like, and obtaining a uniform coating film.

Energy Application

Heating, and radiation irradiation, such as light-exposure, and the like may be used as the energy application method to the base material surface. For example, light-irradiation by a UV lamp, visible light radiation, or the like, and heating with a hot plate or the like may be carried out. Examples of such a light source include a mercury-vapor lamp, a metal halide lamp, a xenon lamp, a chemical lamp, a carbon arc light, and the like. Examples of radiation that may be used include an electron beam, X-rays, an ion beam, far-infrared radiation, and the like. Moreover, g-line, i-line, Deep-UV light, and a high-density energy beam (laser beam) may also be used.

Specific modes for energy application generally used include direct image-pattern recording using a thermal recording head or the like, scanning light-exposure using an infrared laser, high luminosity flash light-exposure using a xenon electric-discharge lamp or the like, and infrared lamp light-exposure.

The duration of energy application depends on the amount of the target graft polymer to be generated and on the light source used, but is normally between 10 seconds and 5 hours.

The polymer layer (graft polymer layer), which includes a polymer containing an interactive group, may be formed on a base material according to the step (a1) as explained above.

Step (a2)

In step (a2), a metal ion or a metal salt is applied to the polymer layer formed in step (a1). In this step, the interactive group of the graft polymer configuring the polymer layer adheres (adsorbs) the applied metal ions or metal salts according to the function of the interactive group.

Metal Ions or Metal Salts

The metal ions or metal salts will now be explained.

There are no particular limitation to the metal salt, as long as it dissolves in a solvent suitable for applying to the polymer layer, and as long as it dissociates to a metal ion and a base (anion), and preferable examples of such a metal salt include M(NO₃)n, MCln, M_{2/n}, (SO₄), and M_{3/n}(PO₄) (wherein M represents a n-valent metal atom). As a metal ion, a dissociated ion of the above metal salt is preferably used.

The metal ion or the metal salt in the present invention are preferably a metal ion or a metal salt of a metal chosen from the group consisting of copper, silver, gold, nickel, and chromium, from the standpoints of the reduced metal not being readily oxidized and being suitable as an electrical material.

Application Method of the Metal Ion and Metal Salt

The method used for applying the metal ion or the metal salt may be suitably chosen in consideration of the compound forming the graft polymer configuring the polymer layer. Moreover, the graft polymer preferably contains a hydrophilic group, from the standpoint of adhesion of metal ions and the like.

Specific methods which may be selected and used for applying the metal ion or metal salt include:

(i) a method of allowing the metal ion to be adsorbed to the ionic group of the graft polymer, when the graft polymer contains an ionic group (polar group) as the interactive group;

(ii) a method of impregnating the graft polymer with the metal salt or a solution containing the metal salt, when the graft polymer is a polymer having high affinity to a metal salt, such as polyvinyl pyrrolidone; and

(iii) a method of immersing the graft polymer in a solution containing or dissolving the metal salt, and impregnating the graft polymer with the metal salt and/or a solution containing the metal salt, when the graft polymer is hydrophilic:

In particular, according to the above method (iii), properties of the graft polymer is not particularly limited and desired metal ion or metal salt may be applied thereto.

In the application of the metal ion or the metal salt to a polymer layer, when the above method (i) of allowing the metal ion to be adsorbed to the ionic group of the graft polymer is used, the above metal salts may be dissolved in a suitable solvent, and the resultant solution containing the dissociated metal ions may be applied onto a substrate surface that has been formed with a polymer layer, or the substrate formed with the polymer layer may be immersed in such a solution. By contacting the solution containing the metal ions, the metal ions can be adsorbed to the ionic groups. From a standpoint of carrying out sufficient adsorption, it is preferable that the concentration of the metal ion or metal salt in the solution is in the range from 1 to 50 mass %, and the range from 10 to 30 mass % is more preferable. Moreover, the contact time is preferably from about 10 seconds to 24 hours, and is more preferably from about 1 minute to 180 minutes.

In the application of the metal ion or the metal salt to a polymer layer, when (ii) the graft polymer is a polymer having high affinity to a metal salt such as polyvinyl pyrrolidone, the metal salt may be attached directly to the polymer layer in the form of microparticles, or may be applied by coating or immersing a substrate surface having the polymer layer thereon with a solution containing dissociated metal ions obtained by dissolving the metal salt with a suitable solvent. By contacting to the solution containing metal ions, the metal ions can be ionically adsorbed to the aforementioned ionic groups. Moreover, when the graft polymer includes a hydrophilic compound, the graft polymer can be impregnated with a dispersion of the metal salt by means of a high water retention ability of the graft polymer. The metal salt concentration of the dispersion liquid, or metal salt concentration, is preferably in the range of from 1 to 50 mass %, and is still more preferably in the range of from 10 to 30 mass %, from a standpoint of ensuring sufficient impregnation with the dispersion. Moreover, the contact time is preferably from about 10 seconds to 24 hours, and is more preferably about 1 minute to 180 minutes.

In application of the metal ion or the metal salt to the graft polymer, when employing method (iii) of immersing a glass substrate having a polymer layer of a hydrophilic graft polymer in a liquid containing the metal salt or in a solution in which the metal salt is dissolved, and impregnating the polymer layer with the metal ions and/or the liquid containing the metal salt, the metal salt can be applied by preparing a dispersion of the metal salt using a suitable solvent or preparing a solution of the dissociated metal ions, and applying the dispersion or solution to a substrate surface having the polymer layer or immersing the substrate in the dispersion or solution. In this way also, as described above, the hydrophilic graft polymer can be impregnated with the dispersion or solution by means of a high water retention ability of the graft polymer. The metal salt concentration of the dispersion liquid, or metal salt concentration, is preferably in the range of from 1 to 50 mass %, and is still more preferably in the range of from 10 to 30 mass %, from a standpoint of ensuring sufficient impregnation with the dispersion or solution. Moreover, the contact time is preferably from about 10 seconds to 24 hours, and is more preferably about 1 minute to 180 minutes.

Relationship between the polarity of the functional group of the graft polymer and the metal ion or metal salt

When the graft polymer has a functional group having a negative charge, a region on which a simple element of metal (metal film or metal microparticles) is deposited can be formed by allowing metal ions having a positive charge to be adsorbed to the functional groups having a negative charge, and then reducing the adsorbed metal ions.

Relationship between the polarity of a hydrophilic group of a hydrophilic compound bonding type and the metal ion or metal salt

When the graft polymer has, as explained above, an anionic group such as a carboxyl group, a sulfonic group or a phosphonic acid group as a hydrophilic functional group, the graft polymer can be selectively negatively charged, and a metal (particle) film region (wiring) can be formed by allowing metal ions having a positive charge to be adsorbed to the functional groups, and then reducing the adsorbed metal ions.

On the other hand, when the graft polymer chain has a cationic group such as an ammonium group, like those described in JP-A No. 10-296895, the polymer is selectively positively charged, and a metal (particle) film region (wiring) can be formed by impregnating the graft polymer with a solution containing the metal salt or a solution dissolving the metal salt, and then reducing the metal ions in the solution or in the metal salts.

Such metal ions are preferably bonded to the hydrophilic groups of the hydrophilic surface at an amount of as much as possible, from the standpoint of durability of bonding.

Methods for applying the metal ions to the hydrophilic groups include: a method of coating a solution in which metal ions or a metal salt has been dissolved or dispersed onto a support surface; and a method of immersing a support surface into such a solution or dispersion. In either way of coating and immersion, an excessive quantity of metal ions are supplied, and the contact duration is preferably from about 10 seconds to about 24 hours, and is still more preferably from about 1 minute to about 180 minutes, so that sufficient ionic bonding with the hydrophilic groups is introduced.

The metal ions or the metal salt may be used singly or in combination of two or more. Moreover, in order to achieve desired conductivity, plural materials may be used by mixing in advance.

In a conductive layer formed by the below-mentioned processes, it may be confirmed, by surface observations and cross-section observations using an SEM and AFM, that the metal particles are dispersed compactly at the surface graft film. The particle sizes of the metal particles formed are from about 1 nm to 1 μm.

Step (a3)

In step (a3), the metal ion or metal salt, applied to the polymer layer in step (a2) above is reduced, thereby forming a conductive layer having a surface resistivity of from 10 to 100 kΩ/square.

Reducing Agent

In the present step, the metal salt or metal ion that has been adsorbed to or impregnated in the graft polymer is reduced. The reducing agent used to form the conductive layer is not particularly limited, as long as it has a property of reducing the metal salt compound that has been used to allow the metal to separate out, and examples thereof include a hypophosphite salt, a tetrahydroboric acid salt, hydrazine, and the like.

The reducing agent is suitably chosen according to their relationship with the metal salt or metal ion used. The reducing agent is preferably sodium tetrahydroborate when an aqueous solution of silver nitrate or the like is used as an aqueous metal salt solution for supplying metal ions or metal salt; and is preferably hydrazine when an aqueous solution of palladium dichloride is used.

Examples of the addition method of the above reducing agent include, for example: a method of applying metal ions or metal salt to a substrate surface which has a polymer layer thereon, washing with water and removing excess metal salt or metal ions, then immersing the substrate in ion exchange water or the like, and adding a reducing agent thereto; and a method of directly coating or dripping an aqueous solution containing the reducing agent at a given concentration onto such a substrate surface. An excess quantity of the reducing agent, i.e., more than the equivalent amount to the metal ions, is preferably used as the addition amount thereof, and it is still more preferable that the addition amount is more than 10 times the equivalent amount.

The presence of a uniform, high strength, conductive layer due to the addition of the reducing agent may be checked with the naked eye from a metallic luster of the surface, and the structure thereof may be checked by observing the surface using a transmission electron microscope or an AFM (atomic force microscope). Moreover, the film thickness of the metal (particles) film may be readily measured by a conventional method such as, for example, observation of a cut face with an electron microscope.

Step (a4)

In step (a4), subsequent to step (a3), electroplating is performed to form a conductive layer having a surface resistivity of 1×10⁻¹ Ω/square or less. Namely, in this step, by using as a base the conductive layer formed in step (a3), and by performing electroplating thereto, a conductive layer having excellent adhesiveness to the substrate and sufficient conductivity is formed.

Known conventional methods may be used for the electroplating method.

Examples of the metal used for electroplating in this process include copper, chromium, lead, nickel, gold, silver, tin, zinc, and the like. From a standpoint of the conductivity thereof, copper, gold, and silver are preferable, and copper is more preferable.

An additive is preferably included in the electroplating bath used for the electroplating in this process, from a standpoint of improving characteristics of the metal film when applied to electronic circuits, such as the smoothness, extendibility, and conductivity characteristics. Commercial electroplating additives for electroplating may be used as such an additive. Specific examples of such additives include, for example, janus green B (JGB), SPS (sulfopropylthiorate), polyethylene glycol, various kinds of surfactants, and the like. Moreover, mixtures thereof marketed by metal plating liquid manufacturers may be used, such as the COPPER GLEAM series made by Meltex Incorporated, the TOP LUCINA series made by Okuno Chemical Industries Co., Ltd., and the CU-BRITE Series made by Ebara-udylite Co., Ltd. These may be selected according to the mechanical characteristics of the metal film to be obtained, and the like.

Specific modes of the type and addition amount of the additive may be suitably adjusted in consideration of various characteristics, such as speed of electroplating, current density during electroplating, and internal stress of the metal film formed. Specifically, the chemical concentration of such an additive may be from 0.1 mg/L to 1.0 mg/L, and for a commercial electroplating liquid from 1 ml/L to 50 ml/L may be added (depending to each manufacturer's catalog).

In step (a4), the electroplating is preferably performed at a current density of from 0.1 to 3 mA/cm² until the consumption of electricity reaches from 1/10 to ¼ of the total consumption of the electricity from the commencement of electric current flow to the termination of electric current flow. By performing electroplating at a small current density for a certain period of time from the start of current flow, a uniform metal coating film can be formed on a substrate having a relatively high surface resistance, and a fine metal film having excellent electrical conductivity and applicability to electronic circuits can be formed, due to the slow growth of the metal film.

The period for performing electroplating at the current density within the above range may be suitably set according to the application or properties and the like of the metal film to be formed, within the time period in which the consumption of electricity reaches from 1/10 to ¼ of the total consumption of the electricity from the commencement of electric current flow to the termination of electric current flow. Moreover, the amount of the current density may also be suitably set within the above range.

The electroplating in this step is further performed by increasing the current density, after performing for a certain time period at a small current density in the above range. The degree of increasing the current density may be appropriately adjusted, but is normally from 2 to 20 times, preferably from 3 to 5 times the current density at the commencement of electric current flow.

There are no particular limitations to the mode of increasing the current density, and modes which may be adopted include a linear increase, a stepwise increase, and an exponential increase. The current density is preferably increased linearly, from the standpoint of uniformity in the metal plating coating film.

The film thickness of the conductive layer formed by electroplating differs according to the application, and may be controlled by adjusting the metal concentration in the plating bath, immersion duration therein, or the current density. It should be noted that the film thickness when applied to general electrical wiring and the like, from the standpoint of conductivity thereof, is preferably 0.3 μm or more, and is more preferably 3 μm or more.

The surface resistivity of the conductive layer formed in step (a4) is 1×10⁻¹ Ω/square or less, and is preferably 1×10⁻² Ω/square or less.

It should be noted that the surface resistivities in the present specification adopt values measured according to a four terminal four probe method and a constant current method, using a resistivity meter, LORESTA EP-MCP-T360, made by Dia Instruments Co., Ltd.

Metal Film Forming Method (2)

The second aspect of the metal film forming method of the present invention includes the steps of:

(b1) a step of providing, on a substrate, a polymer layer that includes a polymer containing a functional group that interacts with a metal colloid, the polymer directly chemically bonding to the substrate;

(b2) a step of applying a metal colloid to the polymer layer; and

(b3) a step of forming a conductive layer having a surface resistivity of 1×10⁻¹ Ω/square or less by electroplating.

Namely, the metal film forming method (2) includes step (b2) of applying a metal colloid to the polymer layer, and forming a conductive layer having a surface resistivity of from 10 to 100 kΩ/square, instead of performing steps (a2) and (a3) of the aforementioned metal film forming method (1).

Step (b1)

In step (b1), a polymer layer, including a polymer containing a functional group that interacts with a metal colloid, the polymer directly chemically bonding to the substrate, is provided on a substrate.

Step (b1) in the metal film forming method (2) is similar to step (a1) in the metal film forming method (1), and preferable modes thereof are also similar.

Step (b2)

In step (b2), a metal colloid is applied to the polymer layer formed in step (b1), and a conductive layer having a surface resistivity of from 10 to 100 kΩ/square is formed thereon. Namely, in this step, the interactive group of the graft polymer which configures the polymer layer adheres (adsorbs) the applied metal colloid, according to the function of the group, thereby forming the conductive layer having a surface resistivity of from 10 to 100 kΩ/square.

Metal Colloid

The metal colloid applied to this step is mainly a zero-valent metal, and examples thereof include Pd, Ag, Cu, Ni, Al, Fe, Co, and the like. In the present invention, Pd and Ag are particularly preferable due to their good handling characteristics, and their high level of catalyzing ability. A metal colloid which has been charge-adjusted is generally used in a technique of attaching a zero-valent metal to the graft polymer (interactive region), and such a metal colloid can be produced by reducing metal ions of the above metal in a solution in the presence of a charged surfactant or a charged protective agent. The charge may be varied by the surfactant used, and selectively adsorbed to the graft pattern by the interaction with the interactive group on the graft pattern.

Metal Colloid Application Method

Methods for applying the metal colloid to the graft polymer include: a method of dispersing the metal colloid in a suitable dispersion medium, or dissolving a metal salt in a suitable solvent, and coating a liquid containing the dissociated metal ions onto the substrate surface carrying the graft polymer, or immersing the substrate carrying the graft polymer in such a dispersion or solution. By contacting the solution containing the metal ions, the metal ions can be adsorbed to the interactive group of the patterned portions, using ion-ion or bipolar-ion interaction. From a standpoint of carrying out sufficient adsorption, it is preferable that the metal ion concentration, or metal salt concentration, of the solution for contacting is in the range from 1 to 50 mass %, and the range from 10 to 30 mass % is still more preferable. Moreover, the contact time is preferably from about 1 minute to 24 hours, and it is more preferably from about 5 minutes to 1 hour.

Step (b3)

The step (b3) in the metal film forming method (2) is similar to step (a4) in the aforementioned metal film forming method (1), and preferable modes thereof are also similar.

According to the metal film forming method of the present invention, as described above, a fine metal pattern may be formed without performing etching, and a metal film with excellent adhesiveness to a substrate and sufficient conductivity may be obtained.

Metal Pattern Forming Method (1)

The first aspect of the metal pattern forming method of the present invention is a metal pattern forming method including the steps of:

(c1) providing, on a substrate, a polymer layer that includes a polymer containing a functional group that interacts with a metal ion or a metal salt, the polymer directly chemically bonding to the substrate;

(c2) applying a metal ion or a metal salt to the polymer layer;

(c3) reducing the metal ion or the metal salt to form a conductive layer having a surface resistivity of from 10 to 100 kΩ/square;

(c4) forming a pattern-shaped resist layer on the conductive layer having a surface resistivity of from 10 to 100 kΩ/square;

(c5) forming a pattern-shaped conductive layer having a surface resistivity of 1×10⁻¹ Ω/square or less by electroplating;

(c6) separating the resist layer; and

(c7) removing the conductive layer formed in step (c3) from the region that has been protected by the resist layer.

The steps (c1) to (c7) of the metal pattern forming method (1) will now be explained.

Step (c1)

In step (c1), a polymer layer that includes a polymer containing a functional group (interactive group) that interacts with a metal ion or a metal salt, the polymer directly chemically bonding to a substrate, is provided on the substrate.

The step (c1) in the metal pattern forming method (1) is similar to the step (a1) in the metal film forming method (1), and preferable modes thereof are also similar.

Step (c2)

In step (c2), a metal ion or a metal salt is applied to the polymer layer.

The step (c2) in the metal pattern forming method (1) is similar to the step (a2) in the metal film forming method (1), and preferable modes thereof are also similar.

Step (c3)

In step (c3), the metal ion or the metal salt applied to the polymer layer in the step (c2) is reduced, and a conductive layer having a surface resistivity of from 10 to 100 kΩ/square is formed.

The step (c3) in the metal pattern forming method (1) is similar to the step (a3) in the metal film forming method (1), and preferable modes thereof are also similar.

Step (c4)

In step (c4), a pattern-shaped resist layer is formed on the conductive layer having a surface resistivity of from 10 to 100 kΩ/square formed in the step (c3).

Such a resist layer may be formed using a photosensitive resist. Photosensitive resists which may be used include photo-curable negative-working resists and photo dissolution positive-working resists that are dissolved by light-exposure.

Examples of photosensitive resists which may be used include: 1. photosensitive dry film resists (DFR); 2. liquid resists; and 3.ED (electrodeposition) resists. These each have their own respective characteristics. Namely, the photosensitive dry film resists (DFR) may be used dry and so their handling is simple. The liquid resists may be made into thin film thickness resists, and so are capable of making patterns with good resolution. The ED (electrodeposition) resists may be made into thin film thickness resists, and so are capable of making patterns with good resolution, and their following characteristics to irregularities on the coating surface are good, and adhesiveness is excellent. The photosensitive resist to be used may be selected in consideration of such characteristics.

When using each of above respective photosensitive resists, the resist may be disposed on the conductive layer formed in the step (c3) in the following manner.

1. Photosensitive Dry Film

A photosensitive dry film generally is sandwiched between a polyester film and a polyethylene film, and is pressure-applied by pressing with a hot roll while releasing the polyethylene film by a laminator.

Formulation, film production methods, and laminating methods of photosensitive dry film resists are described in detail in the specification of Japanese Patent Application No. 2005-103677, at paragraph numbers [0192] to [0372], submitted previously by the present applicant, and the descriptions therein may also be applied in a similar manner in the present invention.

2. Liquid Resist

Coating methods include spray coating, roll coating, curtain coating, and dip coating. For coating both sides at the same time, roll coating and dip coating are preferable from these methods, since coating both sides at the same time is possible thereby.

Liquid resists are described in detail in the specification of Japanese Patent Application No. 2005-188722, at paragraph numbers [0199] to [0219], submitted previously by the present applicant, and the descriptions therein may also be applied in a similar manner in the present invention.

3. ED (Electrodeposition) Resist

ED resists are colloid products formed by suspending fine particles of photosensitive resist in water, and since the particles are charged, when a voltage is applied to the conductor layer, a resist deposits by electrophoresis on the conductor layer, and the colloid bond with each other on the conductor to form a film, and a coating may be formed.

Next, pattern light-exposure and development are performed.

In pattern light-exposure, the base material formed with the resist film on the upper portion of the metal film is adhered to a mask film or a dry plate, and exposed to light in the light-sensitive region of the resist used. When using a film, the film may be adhered in a vacuum baking frame, and exposed. The source of light-exposure may be a point light source if the pattern width is about 100 μm. When forming patterns of widths of 100 μm or less, a parallel light source is preferably used.

Any substance may be used for development as long as it can dissolve unexposed portions when the resist is a photo-curable negative-working type, or exposed portions when the resist is a photo dissolution positive-working type which dissolves by light exposure. However, organic solvents and alkali aqueous solutions are mainly used, and alkali aqueous solutions are preferably used from a standpoint of environmental impact reduction.

Step (c5)

In step (c5), a pattern-shaped conductive layer having a surface resistivity of 1×10⁻¹ Ω/square or less is formed by electroplating. Namely, at this process, by using as a base the conductive layer formed in step (c3), and by further performing electroplating, a pattern-shaped conductive layer is formed with excellent adhesiveness to a substrate, provided with sufficient conductivity.

It should be noted that before carrying out the electroplating of step (c5), it is preferable to perform degreasing and washing to remove any residue from the resist development of the previous process, and to remove any oxide coating present that may be formed on the surface, which has been exposed to light in a previous process, of the conductive layer formed in process (c3).

Distilled water, a dilute acid, or a dilute oxidizing agent aqueous solution may be used for such degreasing and washing, and a dilute acidic oxidizing agent aqueous solution is preferably used. Hydrochloric acid and sulfuric acid may be used as such an acid, and hydrogen peroxide and ammonium persulfate may be used as such an oxidizing agent. The concentration of the acidic oxidizing agent is preferably from 0.01 mass % to 1 mass %, and the treatment is preferably conducted at a temperature of from room temperature to 50° C., for 1 to 30 minutes.

The step (c5) in the metal pattern forming method (1) is similar to the step (a4) in the metal film forming method (1), and preferable modes thereof are also similar.

Step (c6)

In step (c6), the resist layer is separated subsequent to the formation of the conductive layer in step (c5).

Separation can be performed by spraying with a release liquid. Although release liquids vary depending on the type of resist, generally a solvent or a liquid that cause the resist to swell is sprayed to separate the swelled resist.

Step (c7)

In step (c7), the resist layer is removed from the region that has been protected by the conductive layer formed in step (c3).

Removal of the conductive layer is performed by dissolution and removal of the conductive layer. Dissolution and removal may be performed using, as a conductive layer removing liquid, an aqueous solution containing a chelating agent for promoting dissolution of a metal salt, an oxidizing agent for oxidizing and ionizing the metal, an acid for dissolving the metal, and the like, and immersing the substrate in the removing liquid or spraying the removing liquid on the substrate.

Chelating agents which may be used include commercial metal chelators, such as EDTA, NTA, phosphoric acid, and the like. Oxidizing agent which may be used include hydrogen peroxide and peroxy acids (hypochlorous acid, persulfuric acid, and the like), and acids which may be used include sulfuric acid, hydrochloric acid, nitric acid, and the like. A combination of these oxidizing agents, chelating agents, and acids is preferably used in the present invention.

Metal Pattern Forming Method (2)

The second aspect of the metal pattern forming method of the present invention is a metal pattern forming method including the steps of:

(d1) providing, on a substrate, a polymer layer that includes a polymer containing a functional group that interacts with a metal colloid, the polymer directly chemically bonding to the substrate;

(d2) applying a metal colloid to the polymer layer to form a conductive layer having a surface resistivity of from 10 to 100 kΩ/square;

(d3) forming a pattern-shaped resist layer on the conductive layer having a surface resistivity of from 10 to 100 kΩ/square;

(d4) forming, in a region where the resist layer is not formed, a pattern-shaped conductive layer having a surface resistivity of 1×10⁻¹ Ω/square or less by electroplating;

(d5) separating the resist layer; and

(d6) removing the conductive layer formed in step (d4) from the region that has been protected by the conductive layer.

Namely, the metal pattern forming method (2) includes a step (d2) of applying a metal colloid to the polymer layer and forming the conductive layer having a surface resistivity of from 10 to 100 kΩ/square, in place of steps (c2) and (c3) of the metal pattern forming method (1).

Step (d1)

The step (d1) in the metal pattern forming method (2) is similar to the step (a1) in the metal film forming method (1), and preferable modes thereof are also similar.

Step (d2)

In step (d2), a metal colloid is applied to the polymer layer formed in step (d1), and a conductive layer having a surface resistivity of from 10 to 100 kΩ/square is formed.

The step (d2) in the metal pattern forming method (2) is similar to the step (a2) in the metal film forming method (2), and preferable modes thereof are also similar.

Steps (d3) to (d6)

The steps (d3) to (d6) in the metal pattern forming method (2) are similar to respective steps (c4) to (c7) in the metal pattern forming method (1), and preferable modes thereof are also similar.

Metal Pattern Forming Method (3)

The third aspect of the metal pattern forming method of the present invention is a metal pattern forming method including the steps of:

(e1) providing, on a substrate, a pattern-shaped polymer layer that includes a polymer containing a functional group that interacts with a metal ion or a metal salt, the polymer directly chemically bonding to the substrate;

(e2) applying a metal ion or a metal salt to the polymer layer;

(e3) reducing the metal ion or the metal salt to form a conductive layer having a surface resistivity of from 10 to 100 kΩ/square; and

(e4) forming a conductive layer having a surface resistivity of 1×10⁻¹ Ω/square or less by electroplating.

Namely, whereas in the metal pattern forming methods (1) and (2) a polymer layer is formed on a substrate over the entire surface thereof, and a pattern shaped conductive layer is formed on such a polymer layer, in the metal pattern forming method (3) a pattern-shaped polymer layer, including a polymer containing an interactive group, is formed on the substrate, and then the conductive layer is formed on the polymer layer.

The steps (e1) to (e4) of a metal pattern forming method (3) will now be explained.

Step (e1)

In step (e1), a polymer layer including a polymer containing a functional group that interacts with a metal ion or a metal salt, the polymer directly chemically bonding to the substrate is provided on the substrate in a pattern shape.

The following pattern forming modes (1) to (3) can be mentioned as the methods for providing a graft pattern on the substrate in step (e1).

<Pattern Forming Mode (1) of the Present Invention>

Pattern forming mode (1) of the present invention is based on the technique described for step (a1) of the metal film forming method (1), and whereas a polymer layer was formed by energy application over the entire surface of the substrate in the metal film forming method (1), in this mode energy application is performed in a pattern shape, and the polymer layer is thereby formed in the pattern shape (such a surface is sometimes referred to below as a “pattern-formed layer”).

Items which may be applied in this mode, such as each of the elements configuring the substrate (a base material, or an intermediate layer that can be formed on the base material), and a polymer layer, are similar to the corresponding items described in the step (a1) of the metal film forming method (1), and may also be applied in a similar manner.

Pattern (Image) Formation

There are no particular limitations to the method of energy application used for formation of the pattern in the pattern forming mode (1) of the present invention, and any method of energy application may be used as long as active sites are generated on the substrate surface, and bonding of the compound containing the interactive group is achieved. However, irradiating with actinic radiation is preferable from the standpoints of cost and simplicity of equipment.

Pattern forming methods which may be used include writing by heating or radiation irradiation, such as light-exposure and the like. Possible examples thereof include: light-irradiation by an infrared laser, an ultraviolet lamp, visible light radiation, and the like; electron-beam irradiation by γ-rays and the like; and thermal recording by a thermal head, and the like. Examples of such light sources include: a mercury-vapor lamp, a metal halide lamp, a xenon lamp, a chemical lamp, a carbon arc lamp, and the like. Examples of radiation which may be used include an electron beam, X-rays, an ion beam, far-infrared rays, and the like. Furthermore, g-line, i-line, Deep-UV light, and a high-density energy beam (laser beam), may also be used.

Specific example modes for energy application generally used include direct image pattern recording using a thermal recording head or the like, scanning light-exposure using an infrared laser, high luminosity flash light-exposure from a xenon electric-discharge lamp or the like, and infrared lamp light-exposure.

When applying irradiation of actinic radiation for image-wise light-exposure, both scanning light-exposure based on digital data and pattern light-exposure using a lith film may be used.

Thus, the active sites generated at the substrate surface by performing energy application polymerize with the compound containing a polymerizable group and an interactive group, and a graft pattern composed of graft chains having a high mobility is formed. Furthermore, a preferable embodiment is one that, by using a compound that contains polymerizable groups at a terminal and at a side chain thereof, a further graft chain is bonded to the polymerizable group on the side chain of a graft chain that has been bonded to the substrate, thereby forming a branched graft chain structure. According to this embodiment, the formation density and mobility of the graft are dramatically improved, and even greater interaction with an electroless plating catalyst or a precursor thereof is exhibited.

<Pattern Forming Mode (2) of the Present Invention>

The pattern forming mode (2) of the present invention forms a graft pattern by: directly bonding, over the entire surface of a substrate, a polymer compound which has a functional group that transforms into a functional group that interacts with a metal ion or metal salt, or loses its ability (polarity converting group), due to heat, acid, or radiation; and then forms a graft pattern by application of heat, an acid, or radiation thereto.

This embodiment is based on the pattern forming mode (1) of the present invention. In the pattern forming mode (1) the compound containing an interactive group is directly bonded to a substrate surface in a pattern form, and a pattern-formed layer (polymer layer) is formed thereby. On the other hand, in the present mode, a polymer layer is formed over the entire surface of a substrate using a compound containing a polarity converting group, then heat, an acid, or radiation is applied in a pattern shape to transform the polarity converting groups in the region to which energy has been applied into interactive groups, or quench the functionality of the polarity converting group, and a pattern-shaped polymer layer (pattern-formed layer) is formed from the polymer containing an interactive group.

The polarity converting group used for this mode will now be explained. The polarity converting group in this mode may be (A) a type which changes polarity with heat or acid, or (B) a type which changes polarity with radiation (light).

It should be noted that there are no particular limitations to the “functional group that interacts with a metal ion or metal salt” in the present invention, as long as it is a functional group to which the electroless plating catalyst described below, or precursors thereof, may adhere, but it is generally a hydrophilic group.

(A) Functional Group which Changes Polarity with Heat or Acid

First, the functional group which changes polarity with (A) heat or acid will now be explained.

There are two kinds of the type of (A) functional group which changes polarity with heat or acid, such as functional groups which change with heat or acid from being hydrophobic to being hydrophilic, and functional groups which change with heat or acid from being hydrophilic to being hydrophobic.

(A-1) Functional Groups that Change with Heat or Acid from being Hydrophobic to being Hydrophilic

Known functional groups described in publications may be mentioned as (A-1) functional groups which change with heat or acid from being hydrophobic to being hydrophilic.

Useful examples thereof include functional groups such as: alkyl sulfonates, disulfones, and sulfonimides described in JP-A No. 10-282672; alkoxy alkyl esters described in EP0652483 and WO92/9934; t-butyl esters described on page 1477 of Macromolecules, Vol. 21, by H. Ito et al.; and also, carboxylic acid esters protected by an acid decomposable group described in publications, such as silyl esters and vinyl esters.

Moreover, other functional groups which may be used include the following, but there is no limitation thereto: the imino sulfonate group described at page 374 of “Surface” Vol. 133 (1995), by Masahiro Tsunooka; the beta ketone sulfonate esters described at page 2045 of Polymer Preprints, Japan Vol. 46 (1997), by Masahiro Tsunooka; and the nitrobenzyl sulfonate compound described in JP-A No. 63-257750 by Tuguo Yamaoka.

Among such functional groups, particularly excellent groups include the secondary alkyl sulfonate groups and tertiary carboxylate groups represented with Formula (1), and the alkoxy alkyl ester groups represented with Formula (2) described in JP-A No. 2001-117223, and among these the secondary alkyl sulfonate groups represented with Formula (1) are the most preferable. Specific examples of particularly preferable functional groups are shown below.

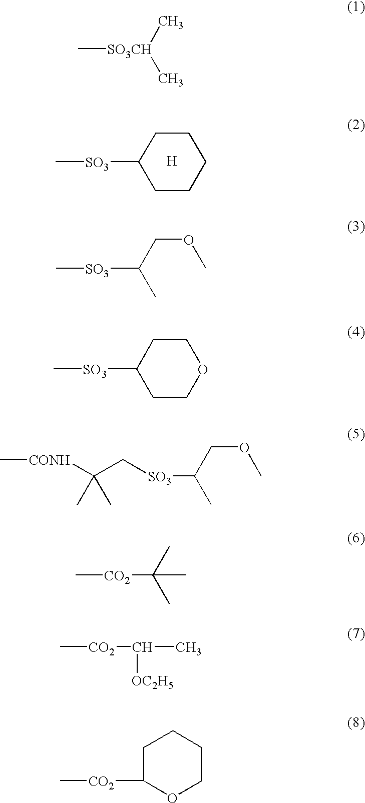

(A-2) Functional Groups that Change with Heat or Acid from being Hydrophilic to being Hydrophobic

In the present invention, examples of (A-2) functional groups which change with heat or acid from being hydrophilic to being hydrophobic include known functional groups, for example, the polymers which include an onium salt group, and in particular polymers containing an ammonium salt, described in JP-A No. 10-296895 and U.S. Pat. No. 6,190,830. Specific examples include (meth)acryloyloxy alkyl trimethylammonium and the like. Moreover, although the carboxylic acid groups and carboxylate groups shown in Formula (3) of JP-A No. 2001-117223 are preferable examples, there is no particular limitation thereto. Specific examples of particularly preferable functional groups are shown below.

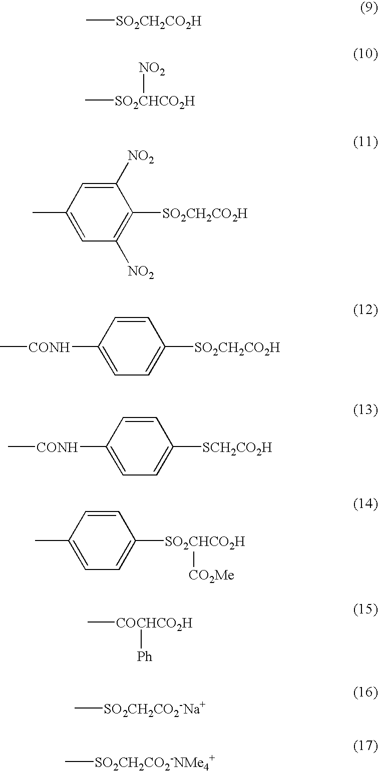

The polymer compound containing a polarity converting group in the present invention may be a homopolymer of a single monomer containing a functional group such as above, or may be a copolymer of two or more thereof such monomers. Moreover, a copolymer including other monomers may be used, as long as the effect of the present invention is not impaired.

Specific examples of (A-1) monomers containing a functional group which changes with heat or acid from being hydrophobic to being hydrophilic are shown below.

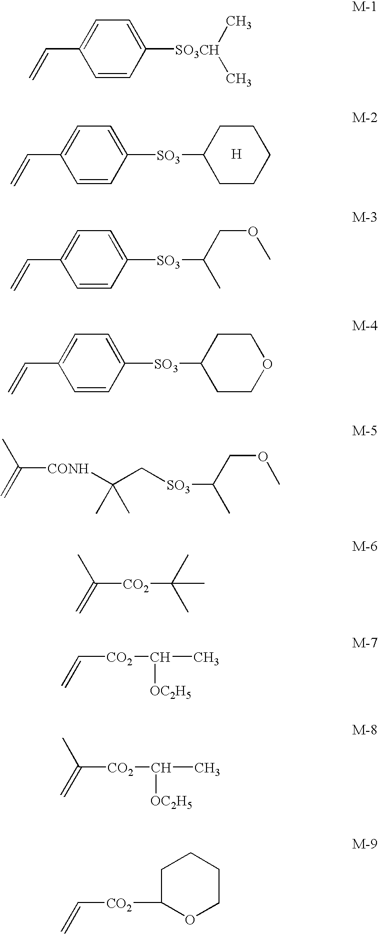

Specific examples of (A-2) monomers containing a functional group that change with heat or acid from being hydrophilic to being hydrophobic are shown below.

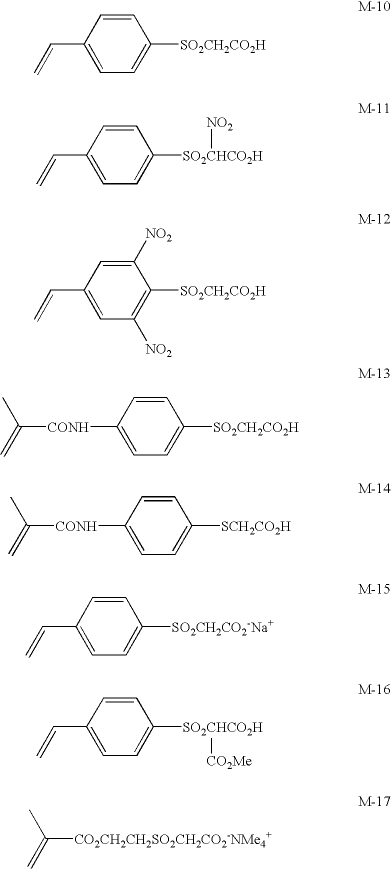

Photothermal Conversion Substance

A photothermal conversion substance for transforming such light energy into thermal energy is preferably included somewhere in the pattern forming material, if the energy provided is light energy, such as an IR laser, when forming the graft pattern at the surface of a pattern forming material containing a polymer compound which has a polarity converting group as described above. The portion in which such a photothermal conversion substance is included may be, for example, any of the pattern-formed layer, intermediate layer and base material, and further, the photothermal conversion substance may be added to a photothermal conversion substance layer that may be provided between the intermediate layer and the base material.

Any material which absorbs light, such as ultraviolet rays, visible rays, infrared rays, or a beam of white light, and is capable of transforming the light into heat may be used as the photothermal conversion substance. Examples thereof include carbon black, carbon graphite, a pigment, a phthalocyanine-containing pigment, iron powder, graphite powder, iron oxide powder, lead oxide, silver oxide, chromium oxide, iron sulfide, chromium sulfide, and the like. Dyes, pigments, or metal particles which have an absorption-maximum wavelength in the range of from 760 nm to 1200 nm, which is the exposure wavelengths of infrared lasers used for energy application, are particularly preferable.

Examples of dyes which may be used include commercial dyes and known dyes described in publications, such as, for example, those described in “Senryo Binran” (Dye Handbook, edited by the Society of Synthetic Organic Chemistry, Japan, 1970). Specific examples of dyes include, azo dyes, metal complex azo dyes, pyrazolone azo dyes, anthraquinone dyes, phthalocyanine dyes, carbonium dyes, quinonimine dyes, methine dyes, cyanine dyes, metal thiolate complexes and the like. Preferable examples of dyes include: cyanine dyes described in JP-A No. 58-125246, JP-A No. 59-84356, JP-A No. 59-202829, JP-A No. 60-78787, and the like; methine dyes described in JP-A No. 58-173696, JP-A No. 58-181690, JP-A No. 58-194595 and the like; naphthoquinone dyes described in JP-A No. 58-112793, JP-A No. 58-224793, JP-A No. 59-48187, JP-A No. 59-73996, JP-A No. 60-52940, JP-A No. 60-63744, and the like; squarylium colorants described in JP-A No. 58-112792, and the like; and cyanine dyes described in U.K. Patent No. 434,875, and the like.

Moreover, the near-infrared absorption sensitizer described in U.S. Pat. No. 5,156,938 is also preferably used. Furthermore, the following may also be preferably used: the substituted arylbenzo(thio)pyrylium salt described in U.S. Pat. No. 3,881,924; the trimethine thiapyrylium salt described in JP-A No. 57-142645 (U.S. Pat. No. 4,327,169); the pyrylium compounds described in JP-A Nos. 58-181051, 58-220143, 59-41363, 59-84248, 59-84249, 59-146063, and 59-146061; the cyanine colorant described in JP-A No. 59-216146; the pentamethine thiopyrylium salt and the like described in U.S. Pat. No. 4,283,475; and the pyrylium compounds described in JP-A Nos. 5-13514 and 5-19702. Moreover, other preferable dyes are the near-infrared absorption dyes shown in Formulas (1) and (II) in the specification of U.S. Pat. No. 4,756,993. Particularly preferable dyes among these are cyanine colorants, squarylium colorants, pyrylium salts, and nickel thiolate complexes.

Pigments which may be used include commercial pigments and pigments described in the Color Index (CI) manual, “Latest Pigment Handbook” (edited by the Japan Pigment Technical Association, published 1977), “Latest Pigment Applied Technology” (CMC publications, published 1986), and “Printing Ink Technology” (CMC publications, published 1984). Types of pigment which may be used include black pigments, yellow pigments, orange pigments, brown pigments, red pigments, purple pigments, blue pigments, green pigments, fluorescent pigments, metal powder pigments, and other polymer-bonded colorants. Specific examples thereof include insoluble azo pigments, azo lake pigments, condensed azo pigments, chelate azo pigments, phthalocyanine pigments, anthraquinone pigments, perylene and perinone pigments, thioindigo pigments, quinacridone pigments, dioxazine pigments, isoindolinone pigments, quinophthalone pigments, dyeing lake pigments, azine pigments, nitroso pigments, nitro pigments, natural pigments, fluorescent pigments, inorganic pigments, carbon black, and the like. Carbon black is preferably used from among these pigments.

From the standpoints of sensitivity and film strength of the photothermal conversion material containing layer, these dyes or pigments may be used at a proportion of from 0.01 to 50 mass % of the total solids in the photothermal conversion material containing layer, and from 0.1 to 10 mass % is preferable. When a dye is used, the amount contained is particularly preferably from 0.5 to 10 mass %, and when a pigment is used, it is particularly preferably from 3.1 to 10 mass %.

Acid Generating Material

When forming a graft pattern at the surface of the pattern forming material using the polymer compound containing the above polarity converting group, in order to apply an acid to carry out polarity conversion, it is preferable to include an acid generating material somewhere in the pattern forming material. The acid generating material may be added, for example, to any of the pattern-formed layer, intermediate layer, and base material.

The acid generating material is a compound which generates an acid by heat or light, and generally, known compounds which generate an acid by light, and mixtures thereof, are used, such as photoinitiators for photo cationic polymerization, photoinitiators for photo-radical polymerization, photo-decoloring agents for colorants, photo discoloring agent, and micro resists, and suitable selection for use may be made therefrom.

Examples thereof include: diazonium salts described in S. I. Schlesinger, Photogr. Sci. Eng., 18,387 (1974), T. S. Bal et al., Polymer, 21,423 (1980), and the like; ammonium salts described in the specifications of JP-A No. 3-140140; phosphonium salts described in U.S. Pat. No. 4,069,055 and the like; iodonium salts described in JP-A No. 2-150848, JP-A No. 2-296514, and the like; sulfonium salts described in J V Crivello et al., Polymer J. 17, 73 (1985), the specification of U.S. Pat. No. 3,902,114, the specifications of European Patents No. 233,567, No. 297,443 and No. 297,442, the specifications of U.S. Pat. No. 4,933,377, No. 4,491,628, No. 5,041,358, No. 4,760,013, No. 4,734,444 and No. 2,833,827, the specifications of German Patent No. 2,904,626, No. 3,604,580 and No. 3,604,581, and the like;

selenonium salts described in J. V. Crivello et al., Macromolecules, 10 (6), 1307 (1977) and the like; onium salts, such as arsonium salts described in C. S. Wen et al., Teh, Proc. Conf. Rad. Curing ASIA, page 478, Tokyo, October (1988), and the like; organic halide compounds described in JP-A No. 63-298339 and the like; organic metal/organic halide compounds described in JP-A No. 2-161445, and the like; photo-acid generating agents containing an o-nitrobenzyl type protecting group described in S. Hayase et al., J. Polymer Sci., 25,753 (1987), JP-A No. 60-198538, JP-A No. 53-133022, and the like; compounds that carry out photolysis and generate sulfonic acid, typified by imino sulfonates, described in JP-A No. 64-18143, JP-A No. 2-245756, JP-A No. 3-140109, and the like; and disulfone compounds described in JP-A No. 61-166544, and the like.

From a standpoint of sensitivity and film strength of the acid generating material-containing layer, the acid generating material may be used at a proportion of from 0.01 to 50 mass % of the total solid in the acid generating material-containing layer, and is preferably used at from 0.1 to 30 mass %.

(B) Functional Groups which Change Polarity with Light

Among functional groups which change polarity, there are some groups whose polarity is changed by light-irradiation of no more than 700 nm or less. Such functional groups (B) (polarity converting groups: polarity converting groups which respond to light of no more than 700 nm) can change polarity with high sensitivity without using long wavelength light-exposure such as infrared radiation or heat, since decomposition, decyclization, or dimerization reaction can be caused directly with light-irradiation of a predetermined wavelength. Functional groups which change polarity by light-irradiation of no more than 700 nm will be explained in the following.

There are also two kinds of functional groups (B) which change polarity with light, such as: (B-1) functional groups which change, with light, from being hydrophobic to being hydrophilic; and (B-2) functional groups which change, with light, from being hydrophilic to being hydrophobic.

(B-1) Functional Groups which Change, with Light, from being Hydrophobic to being Hydrophilic

Examples which may be used for (B-1) functional groups which change, with light, from being hydrophobic to being hydrophilic include the functional groups represented with Formulae (1) to (4), and (7) to (9) shown in JP-A 2003-222972.

(B-2) Functional Groups which Change, with Light, from being Hydrophilic to being Hydrophobic

Examples which may be used for functional groups (B-2) which change, with light, from being hydrophilic to being hydrophobic, include a bispyridinio ethylene group.

Substrate

The substrate used in the pattern forming mode (2) of the present invention includes a surface graft layer to which a terminal of the polymer compound containing a polarity converting group has been chemically bonded, directly or through a trunk polymer compound, and a substrate surface to which a terminal of the polymer compound containing a polarity converting group can be chemically bonded, directly or through a trunk polymer compound. As stated previously, the surface of a substrate itself may have such characteristics, or a substrate including an intermediate layer having such characteristics provided on a base material may be used.

Substrate Surface

The substrate surface may be an inorganic layer or an organic layer, as long as such a substrate surface has characteristics suitable for carrying out graft synthesis to provide a surface graft layer. Moreover, in this mode, since the pattern-formed layer which includes a thin layer of a polymer compound exhibits a change of hydrophilic-hydrophobic nature. Therefore, the polarity at the surface may be either hydrophilic or hydrophobic.

For the intermediate layer, in particular when synthesizing a polymer thin layer of this mode using a photo-graft polymerization method, plasma irradiation graft polymerization method, or radiation irradiation graft polymerization method, the polymer thin layer preferably has an organic surface, and is particularly preferably an organic polymer layer. The following may be used as such an organic polymer: synthetic resins, such as an epoxy resin, an acrylic resin, a urethane resin, a phenol resin, a styrene resin, a vinyl resin, a polyester resin, a polyamide, a melamine, and formalin resin; and natural resins, such as gelatin, casein, cellulose, and starch. However, since graft polymerization initiation starts from removing a hydrogen from the organic polymer in cases of photo-graft polymerization, plasma irradiation graft polymerization, and radiation irradiation graft polymerization methods, a polymer from which a hydrogen may be readily removed is preferable in terms of manufacturability, such as, in particular, an acrylic resin, a urethane resin, a styrene resin, a vinyl resin, a polyester resin, a polyamide resin, an epoxy resin, or the like.

Such an intermediate layer may be served by the above base material itself or may be an intermediate layer provided on such a base material as required.

In this embodiment, in order to make the surface irregularities of the substrate 500 nm or less, it is preferable to prepare the surface of the substrate (when the substrate is made of only a resin film or the like) or the surface of the intermediate layer (when the intermediate layer is formed on the surface of the base material) so that the surface irregularities thereof is no more than 500 nm. In order to make the surface irregularities of a substrate no more than 500 nm, a resin base material with excellent smoothness characteristics may be selected as such a material, and also, when an intermediate layer is provided, the intermediate layer may be formed to have highly uniform film thickness.

Polymerization Initiation Ability Expressing Layer

In the pattern forming mode (2), from the standpoint of efficiently generating active sites and increasing the sensitivity of pattern formation, it is preferable to form a layer which expresses polymerization initiation ability, as an intermediate layer (substrate) surface, by including, in the surface of the above substrate, a polymerizable compound and a polymerization initiator that express polymerization initiation ability upon application of energy.

Such a layer that expresses polymerization initiation ability (in the following, referred to as a polymerizable layer sometimes, for convenience) may be formed by dissolving essential components thereof in a solvent capable of dissolving such essential components, applying the solution to the substrate surface by a method such as coating, and then curing the coating by heating or light-irradiation.

The details of step (a1) of the metal film forming method (1) may be similarly applied to the layer that expresses polymerization initiation ability in the pattern forming mode (2) of the present invention.

Base Material

The details of step (a1) of the metal film forming method (1) may be similarly applied to the base material of the pattern forming mode (2) of the present invention.

Pattern (Image) Formation

Formation of the pattern in the pattern forming mode (2) of the present invention is performed by irradiation with light radiation or the like, or by heating. Moreover, in one mode of light-irradiation in which a photothermal conversion substance is used together, a pattern may be formed by heating using scanning light-exposure, such as with an infrared region laser beam.

As the pattern forming method, a method of writing by heating or radiation irradiation, such as light-exposure and the like, can be mentioned. Possible examples thereof include: light-irradiation by infrared laser, an ultraviolet lamp, visible light, and the like; electron-beam irradiation, such as γ-rays; and thermal recording by a thermal head, and the like. Examples of such light sources include: a mercury-vapor lamp, a metal halide lamp, a xenon lamp, a chemical lamp, a carbon arc lamp, and the like. Examples of radiation rays which may be used include an electron beam, X-rays, an ion beam, far-infrared rays, and the like. Furthermore, g-line and i-line rays, Deep-UV light, and a high-density energy beam (laser beam), may also be used.

Specific example modes of energy application generally used include direct image pattern recording using a thermal recording head or the like, scanning light-exposure using an infrared laser, high luminosity flash light-exposure from a xenon electric-discharge lamp or the like, and infrared lamp light-exposure.

When using a polarity converting group that is sensitive to light of no more than 700 nm, in the pattern-formed layer, any method of light-irradiation may be used as long as polarity conversion can be caused, namely, as long as it is a method capable of changing the hydrophilic-hydrophobic nature of such a polarity converting group, such as by decomposition, decyclization, or dimerization. For example, light-irradiation by an ultraviolet lamp, visible light radiation, and the like may be used. Examples which may be used as such light sources include a mercury-vapor lamp, a metal halide lamp, a xenon lamp, a chemical lamp, a carbon arc lamp, and the like.

In order to perform direct pattern forming using digital data from a computer, the method of making polarity conversion occur by laser light-exposure is preferable. Examples of lasers which may be used include: gas lasers, such as a carbon dioxide gas laser, a nitrogen laser, an argon laser, He/Ne laser, He/Cd laser, and Kr laser; liquid (dye) lasers; solid lasers, such as a ruby laser, and Nd/YAG laser; semiconductor lasers, such as GaAs/GaAlAs, InGaAs lasers; excimer lasers, such as KrF laser, XeCl laser, XeF laser, and Ar₂, and the like.

<Pattern Forming Mode (3)>

The pattern forming mode (3) of the present invention is one in which, a photosensitive layer (hereinafter, such a photosensitive layer according to the pattern forming mode (3) of the present invention is sometimes referred to as an “ablation layer”), including a photothermal conversion substance and a binder is provided on a substrate, and a layer is provided over the entire surface of the photosensitive layer, this layer being formed by a polymer compound containing an interactive group and directly bonding to the surface of the photosensitive layer. A graft pattern is then formed by irradiating an image with radiation.

Photosensitive Layer (Ablation Layer)

The ablation layer in the pattern forming mode (3) of the present invention has a similar function to that of the layer which expresses a polymerization initiation ability provided on the substrate, from the standpoint of being able to efficiently generate active sites and raising the pattern forming sensitivity.

Such an ablation layer includes the later described photothermal conversion substance and a binder, and may also include other additives as required.

In this mode, radiation, such as an irradiated laser beam, is absorbed by a photothermal conversion substance and transformed into heat, thereby causing ablation of the photosensitive layer. The ablation layer is thereby removed (melted, decomposed, volatilized, combusted, or the like). Accompanying this removal, a later described interactive layer is also removed, and an interactive region is selectively formed on the substrate surface thereby.

Moreover, in this mode, a polymerizable compound and a polymerization initiator are preferably added to the ablation layer, as a compound which expresses polymerization initiation ability by applying energy thereto, in order to form the ablation layer as a layer which expresses polymerization initiation ability, from the standpoint of efficiently generating active sites at the ablation layer surface and raising pattern forming sensitivity.

Such an ablation layer may be formed, as a the layer expressing polymerization initiation ability, by dissolving essential components thereof in a solvent capable of dissolving such essential components, and applying the solution to the substrate surface by a method such as coating, and then curing as a film by heating or light-irradiation.

Components which may be included in the ablation layer will be explained below.

Binder

The binder in the pattern forming mode (3) is used in order to heighten film the coating properties, film strength, and the ablation effect, and may be suitably chosen in consideration of compatibility thereof with the photothermal conversion substance, or dispersibility of the photothermal conversion substance.

Examples of the binder which may be used include: copolymers of unsaturated acids, such as (meth)acrylate and itaconic acid, with alkyl(meth)acrylate, phenyl (meth)acrylate, benzyl (meth)acrylate, styrene, α-methylstyrene, and the like; polymers of alkyl methacrylates and alkyl acrylates typified by polymethylmethacrylate; copolymers of alkyl (meth)acrylate with acrylonitrile, vinyl chloride, vinylidene chloride, styrene, and the like; copolymers of acrylonitrile with vinyl chloride and vinylidene chloride; modified cellulose substances with a carboxyl group in the side chain; polyethylene oxide; polyvinyl pyrrolidone; novolak resins obtained from condensation reactions of phenol, o-, m-, p-cresol, and/or xylenol with an aldehyde, acetone or the like; polyethers of epichlorohydrin with bisphenol A; soluble nylons; polyvinylidene chloride; chlorinated polyolefins; copolymers of vinyl chloride with vinyl acetate; polymers of vinyl acetate; copolymers of acrylonitrile with styrene; copolymers of acrylonitrile with butadiene and styrene; polyvinyl alkylether; polyvinyl alkyl ketone; polystyrene; polyurethane; polyethylene terephthalate isophthalate; acetyl cellulose; acetyl propioxycellulose; acetylbutoxycellulose; nitrocellulose; celluloid; polyvinyl butyral; epoxy resins; melamine resins; formalin resins and the like.

It should be noted that in this specification when referring to either or both of “acrylic and methacrylic”, this is sometimes written as “(meth)acrylic”.

The amount of binder contained in the ablation layer is preferably 5 to 95 weight % with respect to the ablation layer solid content, with 10 to 90 weight % more preferable, and 20 to 80 weight % still more preferable.

Polymerizable Compound

There are no particular limitations to the polymerizable compound used together with the binder, as long as it has good adhesiveness to the substrate and is a compound to which a later described compound containing a polymerizable group and an interactive group can be added by energy application, such as actinic radiation irradiation. However, among these a hydrophobic polymer containing a polymerizable group within its molecule is especially preferable.

The binder itself may serve as the polymerizable compound, or the polymerizable compound may be a different compound from the binder.

Specific preferable examples thereof include: diene-containing homopolymers, such as polybutadiene, polyisoprene, and polypentadiene; homopolymers of allyl group containing monomers, such as allyl (meth)acrylate, and 2-allyloxyethyl methacrylate; and in addition, binary or multicomponent copolymers which include as a structural unit a diene-containing homopolymer, such as polybutadiene, polyisoprene, polypentadiene, and the like, or an allyl group-containing monomer, such as styrene, (meth)acrylate ester, and (meth)acrylonitrile; linear or three-dimensional polymers that have a carbon-carbon double bond within their molecules, such as an unsaturated polyester, an unsaturated polyepoxide, an unsaturated polyamide, an unsaturated polyacrylic, high density polyethylene, and the like.

When adding the polymerizable compound to a binder, the amount contained thereof is preferably in the range of from 5 to 95 mass % with respect to the ablation layer solids content, and the range of from 20 to 80 mass % is particularly preferable.

Polymerization Initiator

The polymerization initiators used in the layer having a polymerization initiation ability of the pattern forming mode (1) of the present invention may be used as they are for the polymerization initiator.

The amount contained of the polymerization initiator is preferable in the range of from 0.1 to 70 mass % with respect to the ablation layer solids content, and the range of from 1 to 40 mass % is particularly preferable.

Photothermal Conversion Substance

Any substance may be used for the photothermal conversion substance of the pattern forming mode (3) of the present invention, as long as it is a material which absorbs light, such as ultraviolet rays, visible light radiation, infrared radiation, or a beam of white light, and is capable of converting the light into heat. More specifically, similar dyes and pigments to those of the photothermal conversion substance described in the aforementioned pattern forming mode (1) of the present invention may be used.

From the standpoints of sensitivity and film strength of the photothermal conversion material-containing layer, these dyes or pigments may be used at an amount contained of a proportion of 0.01 to 50 mass % of the total solids in the ablation layer, and preferably at 0.1 to 10 mass %. When a dye is used, the amount contained is particularly preferably from 0.5 to 10 mass %, and when a pigment, the amount contained is particularly preferably from 3.1 to 10 mass %.

Other Additives

In this mode, nitrocellulose is preferably further included in the ablation layer in order to raise the ablation effect. Nitrocellulose decomposes by heat generated by the light absorbing agent absorbing the near-infrared laser beam and efficiently generates low molecular weight gases, thereby promoting removal of the ablation layer.

Ablation Layer Formation

The ablation layer may be provided by dissolving the aforementioned components thereof in a suitable solvent, and coating this on the substrate. There are no particular limitations to the solvent used when coating the ablation layer, as long as it can dissolve each of the above components, such as the photothermal conversion substance and the binder. A solvent whose boiling point is not too high is preferably used, from a standpoint of ease of drying and workability, and specifically solvents with boiling points of from about 40° C. to about 150° C. may be selected.

When forming an ablation layer on a substrate, the coating amount is preferably from 0.05 to 10 g/m² in terms of dry mass, and from 0.3 to 5 g/m² is more preferable.

In the pattern forming mode (3) of the present invention, the ablation layer can be disposed by coating the composition for the ablation layer formation on the surface of a substrate, and removing the solvent therefrom. It is preferable to cure the film by performing heating and/or light-irradiation. It is particularly preferable to carry out pre-curing by light-irradiation after drying with heat, in order to cure the polymerizable compound to a certain degree in advance, since the occurrences of the whole ablation layer coming off after grafting may be effectively suppressed thereby. The rational for using light-irradiation for pre-curing is similar to that described for the photo-polymerization initiator in the pattern forming mode (1).

Conditions of heating temperature and time may be selected so that the coating liquid is sufficiently cured, however, a temperature of 100° C. or less for a time period of 30 minutes or less is preferable from the standpoint of suitability for production, and a drying temperature in the range of from 40° C. to 80° C. and a drying time of 10 minute or less are more preferable.

A light source used for the later described pattern forming may be used for light-irradiation that is optionally carried out after heating and drying. This light-irradiation should preferably apply energy to the extent that the polymerizable compound present in the ablation layer is not completely radical polymerized, even though it may be partially radical polymerized, in view of the subsequent formation of a graft pattern and from the standpoint of not impeding bond formation between the active sites of the ablation layer and the graft chain. The light-irradiation duration depends on the intensity of the light source, but it is generally preferably 30 minutes or less. As a rough guide to such pre-curing, the amount thereof may be such that the residual film proportion after solvent cleaning is 10% or more, and the proportion of initiator remaining after pre-curing is 1% or greater.

Interactive Layer

In the pattern forming mode (3), on the ablation layer is formed an interactive layer containing a polymer compound containing an interactive group that directly chemically bonds to the ablation layer. Moreover, the present mode includes cases in which the graft polymer is directly bonded onto the surface of the ablation layer, and cases in which the graft polymer is bonded via a trunk polymer compound disposed on the ablation layer surface.

A feature of the graft polymer in this mode is that a terminal of the polymer bonds with the ablation layer surface, and a high mobility of the polymer portion which expresses interactiveness can be maintained without restricting it. It is thus thought that this leads to the expression of superior interactiveness to an electroless plating catalyst or a precursor thereof.

The molecular weight of such a graft polymer chain is in the range of from 500 to 5,000,000 Mw, and the molecular weight is preferably in the range of from 1,000 to 1,000,000 Mw, with the range of from 2,000 to 1,000,000 Mw being still more preferable.

It should be noted that in this mode a graft polymer chain that is directly bonded to the ablation layer surface may be referred to as a “surface graft”. As the methods of forming the “surface graft”, the method for forming the “surface graft polymerization” described above may be employed.

Compound Containing a Polymerizable Group and an Interactive Group

Preferable compounds which may be used as the compound containing a polymerizable group and interactive group in this mode are similar to the compounds containing a polymerizable group and an interactive group used in the pattern forming mode (2) of the present invention.

Moreover, solvents, additives, and the like which are used for the composition containing the compound containing a polymerizable group and an interactive group may also be used in a similar manner.

Substrate

The substrate used for pattern forming mode (3) of the present invention is preferably a dimensionally stable plate-shaped member whose surface irregularities are no more than 500 nm, and, specifically, similar substrates to those previously described in process (a1) of the metal film forming method (1), similar base materials and intermediate layers configuring the substrate, and the like, may be used.

Pattern (Image) Formation

In the pattern forming mechanism of this mode, ablation is caused by image-wise irradiation of radiation, removing the photosensitive layer having the interactive surface to expose the substrate that does not have interactiveness, thereby forming an interactive region (pattern).

Pattern forming methods which may be used include writing by heating or radiation irradiation, such as light-exposure. Possible examples thereof include: light-irradiation by infrared laser, an ultraviolet lamp, visible light radiation, and the like; irradiation with an electron beam such as γ-rays; and thermal recording by a thermal head, and the like. Examples of such light sources include: a mercury-vapor lamp, a metal halide lamp, a xenon lamp, a chemical lamp, a carbon arc lamp, and the like. Examples of radiation which may be used include an electron beam, X-rays, an ion beam, far-infrared radiation, and the like. Furthermore, g-line, i-line, Deep-UV light, and a high-density energy beam (laser beam), may also be used.

Specific example modes for energy application generally used include direct image pattern recording using a thermal recording head or the like, scanning light-exposure using an infrared laser, high luminosity flash light-exposure from a xenon electric-discharge lamp or the like, and infrared lamp light-exposure.

In order to perform direct pattern forming using digital data from a computer, the method of causing ablation by laser light-exposure is preferable. Examples of lasers which may be used include: gas lasers, such as a carbon dioxide gas laser, a nitrogen laser, an argon laser, a He/Ne laser, a He/Cd laser, and a Kr laser; liquid (dye) lasers; solid lasers, such as a ruby laser, Nd/YAG laser; semiconductor lasers, such as GaAs/GaAlAs, InGaAs lasers; excimer lasers, such as KrF laser, XeCl laser, XeF laser, and Ar₂, and the like.

Steps (e2) to (e4)

The steps (e2) to (e4) in a metal pattern forming method (3) are similar to the respective steps (a2) to (a4) in the metal film forming method (1).

Metal Pattern Forming Method (4)

The fourth aspect of the metal pattern forming method of the present invention is a metal pattern forming method including the steps of:

(f1) providing, on a substrate, a pattern-shaped polymer layer that includes a polymer containing a functional group that interacts with a metal colloid, the polymer directly chemically bonding to the substrate;

(f2) applying a metal colloid to the polymer layer to form a conductive layer having a surface resistivity of from 10 to 100 kΩ/square; and

(f3) forming a pattern-shaped conductive layer having a surface resistivity of 1×10⁻¹ Ω/square or less by electroplating.

Namely, in the metal pattern forming method (4), the step (f2) of applying a metal colloid to the polymer layer to form a conductive layer having a surface resistivity of from 10 to 100 kΩ/square is performed in place of steps (e2) and (e3) in the metal pattern forming method (3).

Step (a6)

The step (f1) in the metal pattern forming method (4) is similar to the process (a1) in the metal film forming method (1), and preferable modes thereof are also similar.

Step (f2)

In step (f2), a metal colloid is applied to the polymer layer, and a conductive layer having a surface resistivity of from 10 to 100 kΩ/square is formed.

The step (f2) in the metal pattern forming method (4) is similar to the step (b2) in the metal film forming method (2), and preferable modes thereof are also similar.

Step (f3)

The step (f3) in the metal pattern forming method (4) is similar to the step (a4) in the metal film forming method (1), and preferable modes thereof are also similar.

Metal Film and Metal Pattern

The metal film and metal pattern which are obtained by the present invention preferably have a metal film provided over the entire surface, or in local regions, of a substrate having surface irregularities of no more than 500 nm, and more preferably no more than 100 nm. Moreover, the adhesiveness of such a substrate and such a metal film is preferably 0.2 kN/m or more. Namely, there is excellent adhesiveness between the substrate and the metal film, even though the substrate surface is smooth.

More specifically, the metal film and metal pattern (hereinafter, both may be generically referred to as “metal film”) which are obtained in the present invention are formed by: providing, on a substrate with surface irregularities of no more than 500 nm, preferably no more than 100 nm, a polymer layer which includes a polymer that has an interacting ability and directly chemically bonds to the substrate; applying a metal ion or a metal salt to the polymer layer; reducing and depositing a metal, or applying a metal colloid to the polymer layer and thereafter performing electroplating. The adhesiveness between the substrate and the metal film is preferably 0.2 kN/m or greater.

It should be noted that the surface irregularities is a value measured by cutting a substrate, or the metal film after formation thereof, perpendicularly to the substrate surface, and observing the cut face using a SEM.

More specifically, the Rz measured according to JIS B0601, namely “the difference between the average of the Z data from the maximum peak to the fifth highest peak, and the average of the Z data from the minimum valley to the fifth lowest valley”, should be no more than 500 nm.

Moreover, the value of the adhesiveness between the substrate and the metal film, is a value obtained by bonding a copper plate (thickness: 0.1 mm) using an epoxy adhesive (ARALDITE, made by Ciba-Geigy) onto the metal film surface, drying at 140° C. for 4 hours, then conducting a 90 degree peel test according to JIS C6481, or conducting a 90 degree peel test based on JISC6481 by directly peeling off an end portion of the metal film itself.

In a common metal film, a metal film having excellent high frequency characteristics may be obtained by making the irregularities of the substrate surface, i.e., the irregularities of the interface with the metal film, 500 nm or less. However, in a conventional metal film, since the adhesiveness of the substrate and the metal film would fall if the irregularities of the substrate surface are reduced, roughening of the substrate surface by various surface roughening methods cannot be avoided. Consequently, a method of providing a metal film on such a roughened surface is performed, and therefore, the irregularities of the interface in a conventional metal film is generally 1,000 nm or greater.

However, since the metal film obtained by the present invention is in a hybrid state, with the graft polymer directly chemically bonded to the substrate, even though the irregularities of the substrate surface is small, the irregularities at the interface of the metal film (inorganic component) and polymer layer (organic component) obtained are small, and superior adhesiveness may be maintained.

In the metal film obtained according to the present invention, a substrate with surface irregularities of no more than 500 nm is preferably selected, however, with regard to the surface irregularities, no more than 300 nm is more preferable, no more than 100 nm is even more preferable, and most preferable is no more than 50 nm. There are no particular limitations to the lower limit thereof, however, about 5 nm may be considered to be the lower limit from a practical standpoint of the ease of production, and the like. It should be noted that when using the metal film obtained by the present invention as metal wiring, the smaller the irregularities at the interface of the metal which forms the metal wiring and the organic material, the smaller the power loss during high frequency power transmission, and so a small irregularities of the surface are preferable.

As mentioned above, the value of the ten-point average roughness (Rz) is a value according to the method set out in JIS B0601, and the irregularities of the substrate surface is selected to be 500 nm or less, preferably 300 nm or less, even more preferably 100 nm or less, and most preferably 50 nm or less.

For such a smooth substrate, one which itself is smooth, such as a resin substrate, may be selected, or one with relatively large irregularities may be used by regulating the irregularity to be within the preferable range by providing an intermediate layer thereon.

Moreover, the metal film obtained in the present invention preferably has an adhesiveness between the substrate and the metal film of 0.2 kN/m or greater, preferably 0.3 kN/m or greater, and particularly preferably 0.7 kN/m or greater. Here, although there is no upper limit to the value of the above adhesiveness, a sensible range is from about 0.2 to about 2.0 kN/m. In addition, the value of the adhesiveness of a substrate to a metal film in a conventional metal pattern is commonly from about 0.2 to about 3.0 kN/m. Taking this into consideration, it can be seen that the metal film of the present invention has sufficient adhesiveness in practice.

Thus, the metal pattern of the present invention enables the adhesiveness between the substrate and the metal film to be maintained, while suppressing the irregularities at the substrate side interface to a minimum level.

The metal film obtained with the metal film forming method (1) and (2) of the present invention may, for example, be applied as a metal film in various applications, such as an electromagnetic wave shielding film or the like, or may be applied as a semiconductor chip, various electrical wiring boards, FPC, COF, TAB, antennae, multilayer interconnection boards, mother boards and the like, with patterning by etching.

Moreover, the metal patterns obtained by metal pattern forming methods (1) to (4) are also applicable to the various above applications.

### EXAMPLES

In the following, the present invention will be explained in detail with reference to Examples, however, the present invention is not limited thereto.

### Example 1

### Substrate Preparation

Onto the surface of a polyimide film (product name: Kapton, made by DuPont-Toray Co., Ltd.) as a base material, the photopolymerizable composition described below was coated using a rod bar No. 18, dried for 2 minutes at 80° C., and an intermediate layer of 6 μm in thickness was formed thereby.

Light-irradiation using a 400 W high pressure mercury vapor lamp (part number: UVL-400P, made by Riko Kagaku Sangyo Co., Ltd.) was performed for 10 minutes to the substrate provided with the above intermediate layer, and substrate A was prepared.

Intermediate Layer Coating Liquid

| | | |
|---|---|---|
| Allyl methacrylate/methacrylic acid copolymer | 2 | g |
| (copolymerization mole ratio; 80/20, average molecular | | |
| weight; 100,000) | | |
| Ethylene oxide-modified bisphenol A diacrylate | 4 | g |
| (IR125, an agent from Wako Pure Chemical Industries, Ltd.) | | |
| 1-hydroxycyclohexylphenyl ketone | 1.6 | g |
| 1-methoxy-2-propanol | 16 | g |

### Graft Layer Formation

Acrylic acid was coated to the surface of the produced substrate A using a rod bar #6, and a 15 μm thick PP film was laminated on the coated face.

Further irradiation was carried out from above with a UV light (400 W high pressure mercury vapor lamp: UVL-400P, made by Riko Kagaku Sangyo Co., Ltd., irradiation duration; 30 seconds). After light-irradiation, the mask and laminate film were removed and washed with water, and a graft material B grafted with polyacrylic acid was obtained.

### Conductive Layer Formation

After immersing the graft forming material B in a 0.1 mass % aqueous solution of palladium nitrate (made by Wako Pure Chemical Industries, Ltd.) for 1 hour, the resultant was washed with distilled water. This was then immersed in a 0.2M aqueous solution of NaBH₄ for 20 minutes, and was reduced to zero-valent palladium.

The surface resistance of this material as measured using a four-point type surface resistance meter was 50 Ω/square.

The material was subjected to electroplating for 10 minutes with a current amount of 0.5 mA/cm² in an electroplating bath described below, and thereafter was subjected to electroplating for 15 minutes with a current amount of 30 mA/cm². The surface resistance after electroplating was 0.02 Ω/square.

The metal film of Example 1 was thereby formed.

Electroplating Bath Composition

| | | |
|---|---|---|
| Copper sulfate | 38 | g |
| Sulfuric acid | 95 | g |
| Hydrochloric acid | 1 | mL |
| Additive: COPPER GLEAM ST901 | 3 | mL |
| (made by Meltex Incorporated) | | |
| Water | 500 | g |

### Example 2

### Graft Layer Preparation

A coating liquid of polymer P1 containing the following compositions was coated on substrate A produced in a similar manner to Example 1, using a spin coater. The film thickness of the film obtained was 0.8 μm.

### Coating Liquid Composition Formation

| | |
|---|---|
| Hydrophilic polymer P1 | 0.25 g |
| (synthesized by the method shown below) | |
| Water | 5 g |
| Acetonitrile | 3 g |

Hydrophilic Polymer P1 Synthesizing Method

18 g of polyacrylic acid (average molecular weight; 25,000) was dissolved in 300 g of DMAc, and 0.41 g of hydroquinone, 19.4 g of 2-methacryloyloxyethyl isocyanate, and 0.25 g of dibutyltin dilaurate were added thereto, then the resultant was allowed to react at 65° C. for 4 hours. The acid value of the polymer obtained was 7.02 meq/g. The carboxyl group was neutralized in a 1 mol/L aqueous solution of sodium hydroxide, added to ethyl acetate to allow the polymer to precipitate, washed well, and a hydrophilic polymer was obtained.

Light-exposure was performed for 1 minute on the obtained film using a 400 W low pressure mercury lamp. The obtained film was then washed with water, and a graft material C obtained in which exposed portions thereof were changed to hydrophilic was obtained.

Conductive Layer Formation

The obtained graft material C was immersed in a 1 mass % aqueous solution of silver nitrate (made by Wako Pure Chemical Industries, Ltd.) for 10 minutes, and was washed with distilled water. This was then immersed in a 0.2M aqueous solution of NaBH₄ for 20 minutes, and reduced to metallic silver.

The surface resistance of this material as measured by a four-point type surface resistance meter was found to be 100 Ω/square.

Electroplating of this material was carried out for 10 minutes with a current amount of 1 mA/cm² using the same electroplating bath as in Example 1, and electroplating was performed thereafter for 15 minutes with a current amount of 30 mA/cm². The surface resistance after the electroplating was 0.02 Ω/square.

The metal film of Example 2 was thereby formed.

### Example 3

### Graft Forming Material Preparation

A substrate A produced in a similar manner as in Example 1 was immersed in a t-butyl acrylate solution (30 mass %, solvent: propylene glycol monomethyl ether (MFG)), and light-exposure was carried out for 30 minutes in an argon atmosphere using a 400 W high pressure mercury vapor lamp.

After light-irradiation, the obtained film was well washed with propylene glycol monomethyl ether (MFG), and a graft forming material E grafted with poly-t-butyl acrylate was obtained.

### Graft Layer Formation

A liquid of the following composition was coated on the obtained graft forming material E. The film thickness of the poly-t-butyl acrylate film was 0.5 μm.

| | |
|---|---|
| Triphenylsulfonium triflate | 0.05 g |
| Methyl ethyl ketone (MEK) | 1 g |

Next, light-exposure was carried out to the obtained film for 1 minute using a 400 W high pressure mercury vapor lamp, and then post-baking was performed at 90° C. for 2 minutes. The obtained film was then washed with methyl ethyl ketone (MEK), thereby forming a graft material E having the functional groups that have been changed into adsorbent groups (interactive groups) at the exposed portion.

### Conductive Layer Formation

The resultant graft material E was immersed for 1 hour in a liquid produced by the following method, containing silver colloid particles having a positive charge dispersed, then washed with distilled water. Thereafter, electroplating was performed in a similar manner to Example 1, in a similar electroplating bath to Example 1. The metal film of Example 3 was thereby formed.

Positive Charge Silver Colloid Particle Synthesis Method

3 g of bis(1,1-trimethylammoniumdecanoylaminoethyl)disulfide was added to 50 ml of silver perchlorate ethanol solution (5 mM). 30 ml of sodium borohydride solution (0.4 M) was dripped slowly therein, while stirring vigorously, the ions were reduced, and a dispersion liquid of silver particles coated with quaternary ammonium was obtained.

Electroplating of this material was carried out for 10 minutes with a current amount of 0.3 mA/cm² in the above plating bath. Thereafter, electroplating was carried out with a current amount of 30 mA/cm² for 15 minutes, and a metal film was obtained. The surface resistance after the electroplating was 0.02 Ω/square.

### Example 4

### Graft Film Preparation

The film was produced in a similar manner to Example 2, by coating the polymer P1 on a substrate A.

Light-exposure was performed over the entire surface of the obtained film for 1 minute using a 400 W low pressure mercury lamp, the obtained film was then washed with water, and a graft material F having the entire surface changed to hydrophilic was obtained.

### Conductive Layer Formation

The obtained graft material F was then immersed for 10 minutes in a 5 mass % aqueous solution of copper sulfate (made by Wako Pure Chemical Industries, Ltd.), then washed with distilled water. This was then immersed in a 0.2 M aqueous solution of NaBH₄ for 20 minutes, and reduced to metallic copper. The surface resistance of this material as measured by a four-point type surface resistance meter was 20 Ω/square.

### Metal Pattern Formation

A dry film resist was laminated onto the material with the conductive layer formed as above (120° C., linear velocity; 1 minute/m, 0.5 Pa). Using a mask aligner produced by Mikasa, Inc, light-exposure was carried out to the obtained film with a pattern of line width/spacing (L/S)=5 μm/25 μm, a pattern of L/S=10 μm/20 μm, and a solid portion of 3 cm×6 cm. A resist pattern was obtained after developing in a 1% NaCO₃ bath.

Electroplating of this material was carried out for 10 minutes with a current amount of 0.5 mA/cm² using a similar electroplating bath to in Example 1, and electroplating was carried out thereafter with a current amount of 30 mA/cm² for 15 minutes, and metal thin film patterns were obtained. The surface resistance after the electroplating was 0.02 Ω/square.

The resist was removed using a 1% NaOH bath at 50° C., then after separating the resist, treatment was carried out at 40° C. for 20 minutes with a liquid of 10 times diluted soft etching liquid produced by Meltex with and a conductive layer formed on the portions that had been covered with the resist. The metal pattern of Example 4 was thereby formed.

Evaluation

1. Film Thickness Measurement of Metal Film

The obtained metal films in Examples 1 to 4 were cut perpendicularly to the substrate surface using a microtome, and the cut faces were observed with a SEM, and the thicknesses of the formed metal films were measured. The measurements represent the average of three measured points for each sample. Test results are shown in the following table 1.

2. Irregularity Evaluation of Substrate Interface

The irregularities of the substrate interface were checked by cutting the metal films obtained in Examples 1 to 4 perpendicularly to the substrate surface using a microtome and observing the cut faces using a SEM. Next, three positions at the substrate interface were selected at random as the observation points for each sample, and the difference of the maximum peak height and lowest valley depth at each observation point was taken as the size of irregularities, and the average value of the three positions was calculated. Test results are shown in the following table 1.

3. Evaluation of Adhesiveness

A copper plate (0.1 mm) was adhered to each of the surfaces of the metal thin films obtained in Examples 1 to 3 using an epoxy adhesive (ARALDITE, made by Ciba-Geigy), and after drying at 140° C. for 4 hours, a 90 degree peel test was conducted according to JIS C6481. In Example 4, the peel strength was measured by the same method as above, but on the surface of a solid portion of 3 cm×6 cm in the metal thin film. Test results are shown in the following table 1.

TABLE 1

| | | Substrate interface | |
|---|---|---|---|
| | Metal film thickness | irregularity | Peel strength |
| | (μm) | (μm) | (kN/m) |
| Example 1 | 11.2 | 0.05 | 0.85 |
| Example 2 | 10.5 | 0.08 | 0.92 |
| Example 3 | 10.8 | 0.04 | 0.84 |
| Example 4 | 11.3 | 0.06 | 0.93 |

4. Measurement of Thin Line Width Metal Pattern

The width of the thin line metal pattern obtained in Example 4 was measured using an optical microscope (OPTI PHOTO-2, made by NIKON Corporation). The average of three measured points was calculated for each sample. The line width of the copper pattern portion of L/S=5 μm/25 μm was 5.5 μm, and the line width of the copper pattern portion of L/S=10 μm/20 μm was 10.5 μm.

As shown in Table 1, it was found that each metal pattern obtained in the Examples had a copper thickness with which sufficient conductivity could be attained.

Furthermore, in the metal pattern obtained according to the Examples, while in each of the Examples the irregularities at the film interface exhibit excellent surface smoothness of no more than 100 mm, excellent adhesiveness between the substrate and the metal film was also obtained.

Moreover, in the metal pattern obtained according to the Examples, it can be seen that thin lines having a width of no more than 10 μm were formed. In addition, it was found that the width of the thin lines were controllable by the forming method of the graft pattern and the conditions of exposure.

The entire disclosure of Japanese Patent Application 2005-323442 is incorporated by reference herein.

All publications, patent applications, and technical standards mentioned in this specification are herein incorporated by reference to the same extent as if each individual publication, patent application, or technical standard was specifically and individually indicated to be incorporated by reference.

1. A method for forming a metal film comprising:
(a1) a step of providing, on a substrate, a polymer layer that comprises a polymer containing a functional group that interacts with a metal ion or a metal salt, the polymer directly chemically bonding to the substrate;
(a2) a step of applying a metal ion or a metal salt to the polymer layer;
(a3) a step of reducing the metal ion or the metal salt to form a conductive layer having a surface resistivity of from 10 kΩ/square to 100 kΩ/square; and
(a4) a step of forming a conductive layer having a surface resistivity of 1×10⁻¹ Ω/square or less by electroplating.

2. The method for forming a metal film according to claim 1, wherein the metal ion or the metal salt comprises a metal ion or a salt of a metal chosen from the group consisting of copper, silver, gold, nickel, and chromium.

3. The method for forming a metal film according to claim 1, wherein an electroplating bath used for the step (a4) includes an additive.

4. The method for forming a metal film according to claim 1, wherein the electroplating in the step (a4) is performed at a current density of from 0.1 mA/cm² to 3 mA/cm² until consumption of electricity reaches from 1/10 to ¼ of the total consumption of the electricity from the commencement of electric current flow to the termination of electric current flow.

5. The method for forming a metal film according to claim 1, wherein the substrate has surface irregularities of no more than 500 nm.

6. A method for forming a metal film comprising:
(b1) a step of providing, on a substrate, a polymer layer that comprises a polymer containing a functional group that interacts with a metal colloid, the polymer directly chemically bonding to the substrate;
(b2) a step of applying a metal colloid to the polymer layer to form a conductive layer having a surface resistivity of from 10 kΩ/square to 100 kΩ/square; and
(b3) a step of forming a conductive layer having a surface resistivity of 1×10⁻¹ Ω/square or less by electroplating.

7. The method for forming a metal film according to claim 6, wherein the substrate has surface irregularities of no more than 500 nm.

8. A metal film formed according to the method for forming a metal film of claim 1, wherein surface irregularities of the metal film are no more than 500 nm.

9. A metal film formed according to the method for forming a metal film of claim 1, wherein an adhesive force of the metal film to the substrate is 0.5 kN/m or more.

10. A method for forming a metal pattern comprising:
(c1) a step of providing, on a substrate, a polymer layer that comprises a polymer containing a functional group that interacts with a metal ion or a metal salt, the polymer directly chemically bonding to the substrate;
(c2) a step of applying a metal ion or a metal salt to the polymer layer;
(c3) a step of reducing the metal ion or the metal salt to form a conductive layer having a surface resistivity of from 10 kΩ/square to 100 kΩ/square;
(c4) a step of forming a pattern-shaped resist layer on the conductive layer having a surface resistivity of from 10 kΩ/square to 100 kΩ/square;
(c5) a step of forming, in a region where the resist layer is not formed, a pattern-shaped conductive layer having a surface resistivity of 1×10⁻¹ Ω/square or less by electroplating;
(c6) a step of separating the resist layer; and
(c7) a step of removing the conductive layer formed in the step (c3) from the region that has been protected by the resist layer.

11. The method for forming a metal pattern of claim 10, wherein the substrate has surface irregularities of no more than 500 nm.

12. A method for forming a metal pattern comprising:
(d1) a step of providing, on a substrate, a polymer layer that comprises a polymer containing a functional group that interacts with a metal colloid, the polymer directly chemically bonding to the substrate;
(d2) a step of applying a metal colloid to the polymer layer to form a conductive layer having a surface resistivity of from 10 kΩ/square to 100 kΩ/square;
(d3) a step of forming a pattern-shaped resist layer on the conductive layer having a surface resistivity of from 10 kΩ/square to 100 kΩ/square;
(d4) a step of forming, in a region where the resist layer is not formed, a pattern-shaped conductive layer having a surface resistivity of 1×10⁻¹ Ω/square or less by electroplating;
(d5) a step of separating the resist layer; and
(d6) a step of removing the conductive layer formed in the step (d2) from the region that has been protected by the resist layer.

13. The method for forming a metal pattern according to claim 12, wherein the substrate has surface irregularities of no more than 500 nm.

14. A method for forming a metal pattern comprising:
(e1) a step of providing, on a substrate, a pattern-shaped polymer layer that comprises a polymer containing a functional group that interacts with a metal ion or a metal salt, the polymer directly chemically bonding to the substrate;
(e2) a step of applying a metal ion or a metal salt to the polymer layer;
(e3) a step of reducing the metal ion or the metal salt to form a conductive layer having a surface resistivity of from 10 kΩ/square to 100 kΩ/square; and
(e4) a step of forming a conductive layer having a surface resistivity of 1×10⁻¹ Ω/square or less by electroplating.

15. The metal pattern forming method according to claim 14, wherein the substrate has surface irregularities of no more than 500 nm.

16. A method for forming a metal pattern comprising:
(f1) a step of providing, on a substrate, a pattern-shaped polymer layer that comprises a polymer containing a functional group that interacts with a metal colloid, the polymer directly chemically bonding to the substrate;
(f2) a step of applying a metal colloid to the polymer layer to form a conductive layer having a surface resistivity of from 10 kΩ/square to 100 kΩ/square; and
(f3) a step of forming a pattern-shaped conductive layer having a surface resistivity of 1×10⁻¹ Ω/square or less by electroplating.

17. The method for forming a metal pattern according to claim 16, wherein the substrate has surface irregularities of no more than 500 nm.

18. A metal pattern formed according to the method for forming a metal pattern of claim 10, wherein surface irregularities of the metal pattern are no more than 500 nm.

19. A metal pattern formed according to the method for forming a metal pattern of claim 10, wherein an adhesive force of the metal pattern to the substrate is 0.5 kN/m or more.

20. A metal film formed according to the method for forming a metal film of claim 6, wherein surface irregularities of the metal film are no more than 500 nm.

21. A metal film formed according to the method for forming a metal film of claim 6, wherein an adhesive force of the metal film to the substrate is 0.5 kN/m or more.

22. A metal pattern formed according to the method for forming a metal pattern of claim 12, wherein surface irregularities of the metal pattern are no more than 500 nm.

23. A metal pattern formed according to the method for forming a metal pattern of claim 12, wherein an adhesive force of the metal pattern to the substrate is 0.5 kN/m or more.

24. A metal pattern formed according to the method for forming a metal pattern of claim 14, wherein surface irregularities of the metal pattern are no more than 500 nm.

25. A metal pattern formed according to the method for forming a metal pattern of claim 14, wherein an adhesive force of the metal pattern to the substrate is 0.5 kN/m or more.

26. A metal pattern formed according to the method for forming a metal pattern of claim 16, wherein surface irregularities of the metal pattern are no more than 500 nm.

27. A metal pattern formed according to the method for forming a metal pattern of claim 16, wherein an adhesive force of the metal pattern to the substrate is 0.5 kN/m or more.
